(19) United States
(12) Patent Application Publication
(10) Pub. No.: US 2024/0030112 A1
(43) Pub. Date: Jan. 25, 2024

(54) SEMICONDUCTOR DEVICE

(71) Applicant: ROHM CO., LTD., Kyoto-shi (JP)

(72) Inventors: Hiroto SAKAI, Kyoto-shi (JP); Yuta OKAWAUCHI, Kyoto-shi (JP); Ryosuke FUKUDA, Kyoto-shi (JP); Xiaopeng WU, Kyoto-shi (JP); Kohei TANIKAWA, Kyoto-shi (JP)

(21) Appl. No.: 18/480,186

(22) Filed: Oct. 3, 2023

Related U.S. Application Data
(63) Continuation of application No. PCT/JP2022/018054, filed on Apr. 18, 2022.

(30) Foreign Application Priority Data
Apr. 22, 2021 (JP) 2021-072585

(51) Int. Cl. H01L 23/495; H01L 23/00

(52) U.S. Cl. CPC H01L 23/49575; H01L 24/40; H01L 24/48; H01L 24/73; H01L 2224/40137; H01L 2224/48175; H01L 2224/73221

(57) ABSTRACT

A semiconductor device includes two semiconductor elements for switching, a first conductor electrically connecting the second electrodes of the two semiconductor elements, a second conductor electrically connecting the second electrodes, and a first power terminal electrically connected to the first conductor and the second electrodes of the first semiconductor elements. The two first semiconductor element are connected in parallel with each other. A first conduction path and a second conduction path are provided between the second electrodes of the two semiconductor elements and extend through the first conductor and the second conductor, respectively. The first conduction path and the second conduction path are at least partially in parallel. The combined inductance of the first conduction path and the second conduction path is smaller than the inductance of the first conduction path.

### TECHNICAL FIELD

The present disclosure relates to a semiconductor device.

### BACKGROUND ART

Conventionally, a semiconductor device comprising a power semiconductor element such as a MOSFET (Metal Oxide Semiconductor Field Effect Transistor) or an IGBT (Insulated Gate Bipolar Transistor) has been known. In this semiconductor device, it has been known that the power semiconductor elements are configured to be connected in parallel to ensure the allowable electric power of the semiconductor device (e.g., JP-A-2016-225493). The configuration disclosed in JP-A-2016-225493 (a power module) includes first semiconductor elements, first connection wirings, a wiring layer, and a signal terminal. The first semiconductor elements are, for example, MOSFETs. Each first semiconductor element is turned on/off depending on a drive signal inputted to a gate terminal. The first semiconductor elements are connected in parallel. Each first connection wiring, such as a wire, is connected to the gate terminal of each first semiconductor element and the wiring layer. The wiring layer is connected to the signal terminal. The signal terminal is connected to the gate terminal of each first semiconductor element via the wiring layer and first connection wirings. The signal terminal provides a drive signal to the gate terminal of each first semiconductor element for driving each first semiconductor element.

### BRIEF DESCRIPTION OF THE DRAWINGS

FIG. 1 is a perspective view of a semiconductor device according to a first embodiment.

FIG. 2 is a perspective view of a semiconductor device shown in FIG. 1 from which a resin member and a part of a case (a top plate) are omitted.

FIG. 3 is a plan view of a semiconductor device according to a first embodiment.

FIG. 4 is a plan view of a semiconductor device shown in FIG. 3 from which a resin member and a part of a case (a top plate) are omitted.

FIG. 5 is a partially enlarged plan view in which a portion (right half) of FIG. 4 is enlarged.

FIG. 6 is a partially enlarged plan view in which a portion (left half) of FIG. 4 is enlarged.

FIG. 7 is a front elevational view of a semiconductor device according to a first embodiment.

FIG. 8 is a bottom view of a semiconductor device according to a first embodiment.

FIG. 9 is a cross-sectional view of FIG. 4 taken along a line IX-IX.

FIG. 10 is a cross-sectional view of FIG. 4 taken along a line X-X.

FIG. 11 is a cross-sectional view of FIG. 4 taken along a line XI-XI.

FIG. 12 is a cross-sectional view of FIG. 4 taken along a line XII-XII.

FIG. 13 is a cross-sectional view of FIG. 4 taken along a line XIII-XIII.

FIG. 14 a plan view of a semiconductor device according to a second embodiment from which a resin member and a part of a top plate are omitted.

FIG. 15 is partially enlarged plan view in which a portion of FIG. 14 is enlarged.

FIG. 16 is a cross-sectional view of FIG. 14 taken along a line XVI-XVI.

FIG. 17 is a plan view of a semiconductor device according to a first variant of a second embodiment from which a resin member and a part of a case (a top plate) are omitted.

FIG. 18 is a perspective view of a semiconductor device according to a second variant of a second embodiment.

FIG. 19 is a perspective view shown in FIG. 18 from which a sealing member is omitted.

FIG. 20 is a plan view of a semiconductor device according to a second variant of a second embodiment from which a sealing member is omitted.

FIG. 21 is a plan view shown in FIG. 20 from which a sealing member and one of connection members are omitted.

FIG. 22 is a plan view of a semiconductor device according to a third embodiment from which the resin member and a part of the case (the top plate) are omitted.

FIG. 23 is a partially enlarged cross-sectional view of FIG. 22 taken along a line XXIII-XXIII.

FIG. 24 is a partially enlarged cross-sectional view of FIG. 22 taken along a line XXIV-XXIV.

FIG. 25 is a partially enlarged cross-sectional view of FIG. 22 taken along a line XXV-XXV.

FIG. 26 is a perspective view of a semiconductor device according to a third embodiment.

FIG. 27 is a plan view of a semiconductor device according to a third embodiment from which the sealing member is indicated by imaginary lines (double chain lines).

FIG. 28 is a cross-sectional view of FIG. 27 taken along a line XXVIII-XXVIII.

FIG. 29 is a plan view of a first switching part according to a variant.

FIG. 30 is a cross-sectional view of FIG. 29 taken along a line XXX-XXX.

FIG. 31 is a cross-sectional view of FIG. 29 taken along a line XXXI-XXXI.

FIG. 32 a plan view of a semiconductor device according to a fourth embodiment from which the resin member and a part of the case (the top plate) are omitted.

### DETAILED DESCRIPTION OF EMBODIMENTS

The following describes preferred embodiments of semiconductor devices of the present disclosure in detail with reference to the drawings. In the following, the same reference numerals are given to the same or similar components, and redundant descriptions thereof are omitted. In the present disclosure, the terms “first,” “second,” “third,” etc. are used merely for the purpose of identification, and are not necessarily intended to order their objects.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”.

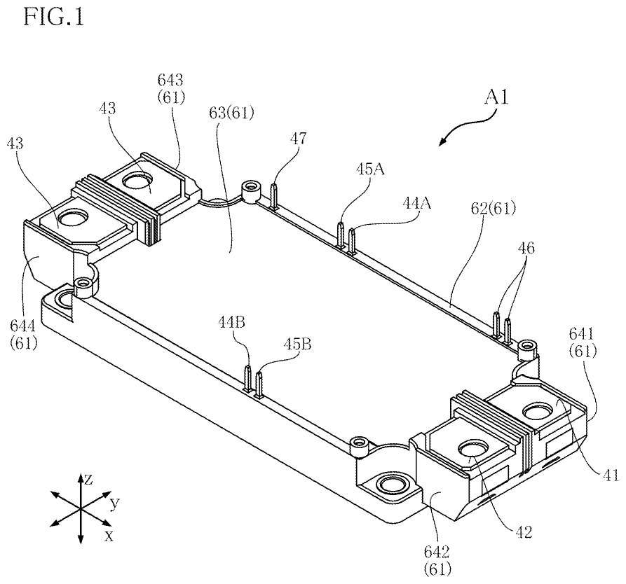

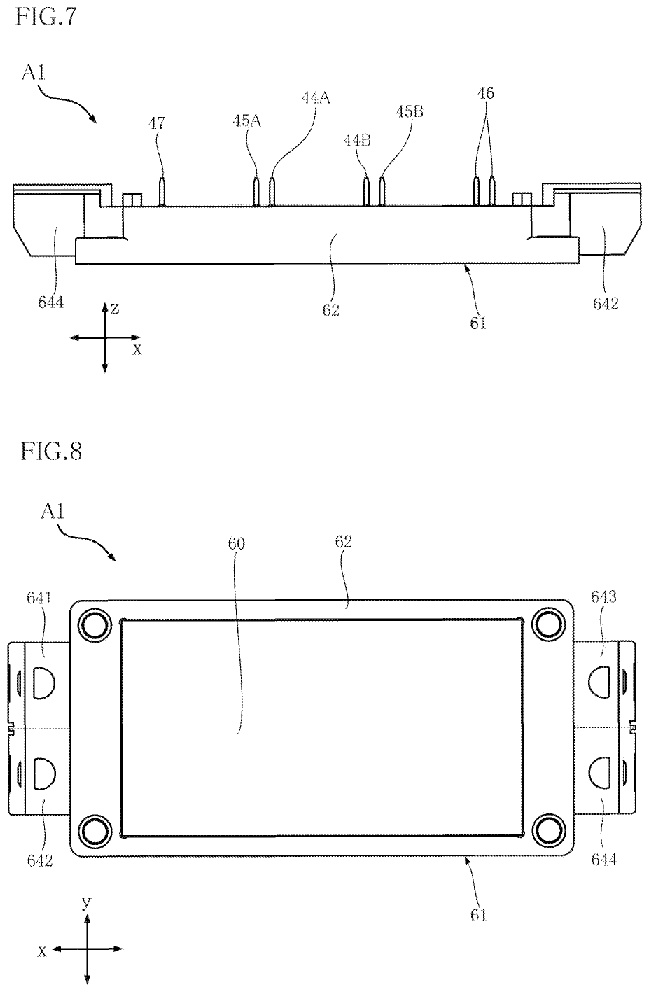

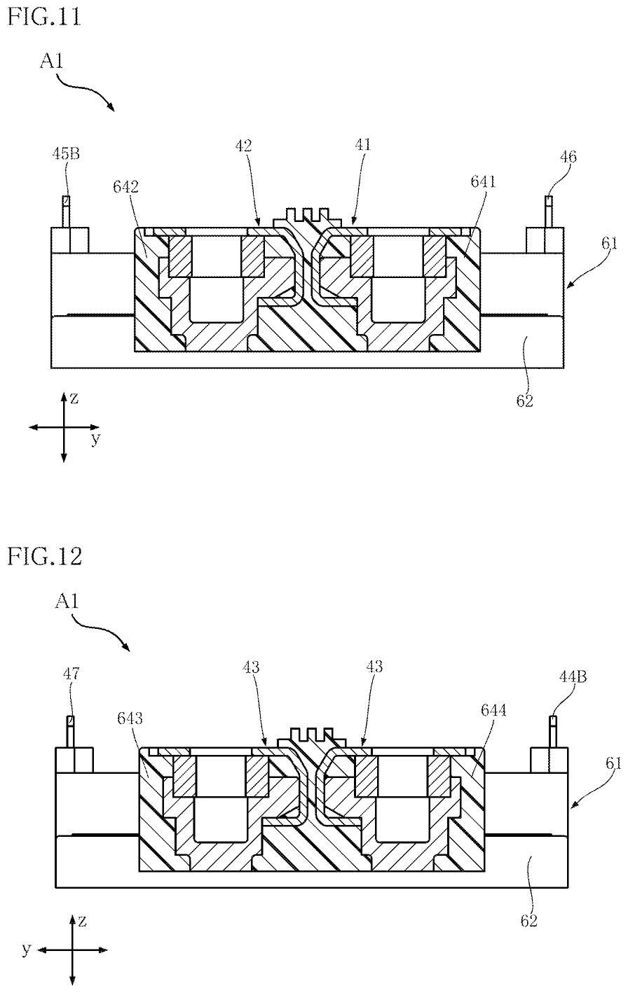

FIGS. 1 to 13 show a semiconductor device A1 according to a first embodiment. The semiconductor device A1 includes a plurality of first semiconductor elements 11, a plurality of second semiconductor elements 21, an insulating substrate 30, a plurality of power wiring parts 311, 312, 313, a plurality of signal wiring parts 321A, 321B, 322A, 322B, 323, a plurality of power terminals 41, 42, 43, a plurality of signal terminals 44A, 44B, 45A, 45B, 46, 47, a plurality of connection members, a heat dissipation plate 60, a case 61, and a resin member 65. As the plurality of connection members, the semiconductor device A1 includes a plurality of connection members 51A, 51B, 52A, 52B, 531A, 531B, 532A, 532B, 541A, 541B, 542A, 542B, 55, 56. As understood from the configurations discussed below, the semiconductor device A1 includes a power wiring part 311 as an example of “a first wiring part”, a power wiring part 313 as an example of “a second wiring part”, and a power wiring part 312 as an example of “a third wiring part”. The semiconductor device A1 also includes a power terminal 43 as an example of “a first power terminal”, a power terminal 42 as an example of “a second power terminal”, and a power terminal 41 as an example of “a third power terminal”. Further, the semiconductor device A1 includes a connection member 51A as an example of “a first connection member”, a connection member 52A as an example of “a second connection member”, and a connection member 51B as an example of “a third connection member”.

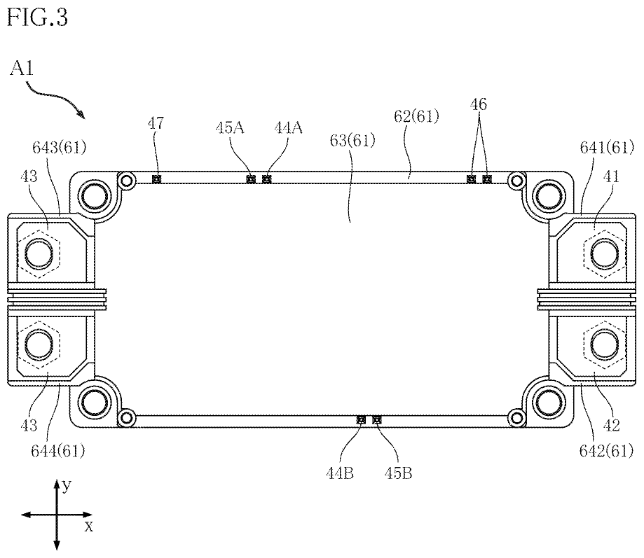

For convenience of explanation, the thickness direction of the semiconductor element 11 is referred to as a “thickness direction z”. In the following description, the expression “as viewed in a plan view” has the same meaning as the expression as viewed in the thickness direction”. A direction perpendicular to the thickness direction z is referred to as a “first direction x”. The first direction x is, for example, a horizontal direction of the plan view of the semiconductor device A1 (see FIG. 3). A direction perpendicular to both the thickness direction z and the first direction x is referred to as a “second direction y”. The second direction y is, for example, a vertical direction of the plan view of the semiconductor device A1 (see FIG. 3).

Each of the first semiconductor elements 11 and each of the second semiconductor elements 21 are MOSFETs, for example. Each first semiconductor element 11 and each second semiconductor element 21 may be provided by other kinds of switching elements, for example, a field effect transistor such as a MISFET (Metal-Insulator-Semiconductor FET) or a bipolar transistor such as an IGBT. Each first semiconductor element 11 and each second semiconductor element 21 are made of SiC (silicon carbide). The semiconductor material is not limited to SiC, but may be Si (silicon), GaAs (gallium arsenide), GaN (gallium nitride), or Ga₂O₃ (gallium oxide) etc.

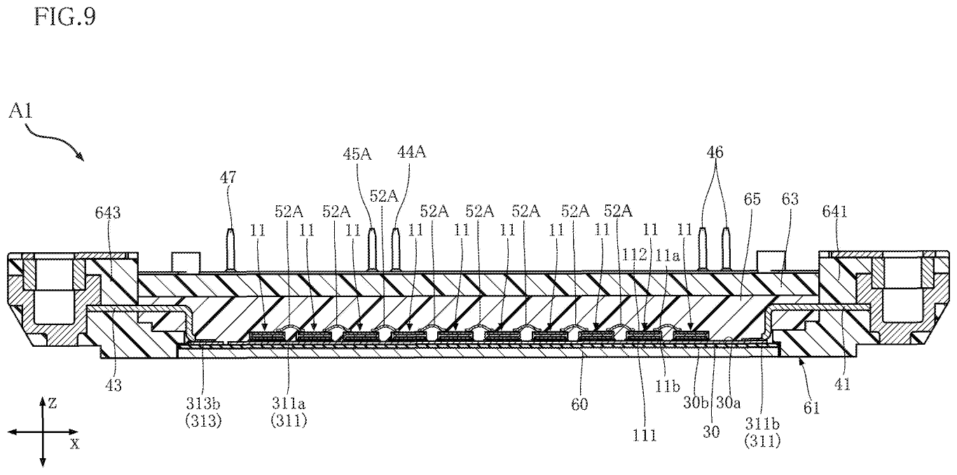

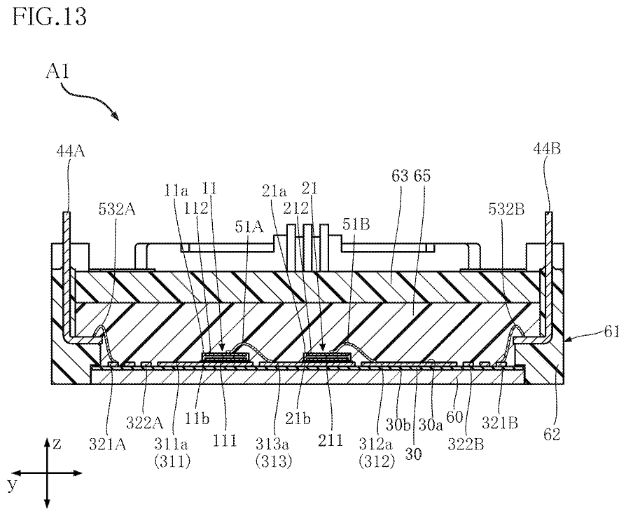

As shown in FIGS. 9 and 13, each first semiconductor element 11 has a first element obverse face 11a and a first element reverse face 11b. The first element obverse face 11a and the first element reverse face 11b are spaced apart from each other in the thickness direction z. The first element obverse face 11a faces one side (upside) of the thickness direction z, while the first element reverse face 11b faces the other side (downside) of the thickness direction z.

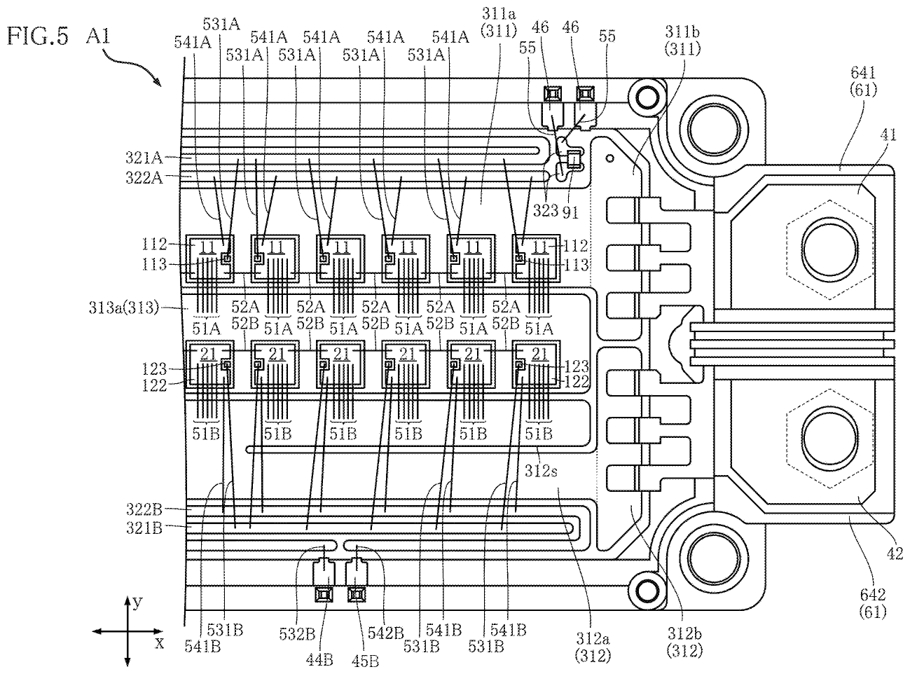

As shown in FIGS. 5, 6, 9 and 13, each first semiconductor element 11 has a first electrode 111, a second electrode 112, and a third electrode 113. In an example where each first semiconductor element 11 is a MOSFET, the first electrode 111 is a drain electrode, the second electrode 112 is a source electrode, and the third electrode 113 is a gate electrode. In each first semiconductor element 11, the first electrode 111 is, as shown in FIGS. 9 and 13, disposed on the first element reverse face 11b, while the second electrode 112 and the third electrode 113 are, as understood from FIGS. 5, 6, 9 and 13, disposed on the first element obverse face 11a.

A first driving signal (e.g. a gate voltage) is inputted to the third electrode 113 (the gate electrode) of each first semiconductor element 11. Each first semiconductor element 11 switches between a conducting state and an interrupting state depending on the inputted first driving signal. This operation between the conducting state and the interrupting state is referred to as a switching operation. A current flows from the first electrode 111 (the drain electrode) to the second electrode 112 (the source electrode) in the conducting state, while the current does not flow in the interrupting state. In other word, the first driving signal (e.g. a gate voltage), which is inputted to the third electrode 113 (the gate electrode), controls on/off between the first electrode 111 (the drain electrode) and the second electrode 112 (the source electrode) in each first semiconductor element 11. A switching frequency of each semiconductor element 11 depends on the frequency of the first driving signal.

The plurality of first semiconductor elements 11 have a configuration as described in detail below, such that their first electrodes 111 (the drain electrodes) are electrically connected to each other, and their second electrodes 112 (the source electrodes) are electrically connected to each other. As a result, the first semiconductor elements 11 are electrically connected in parallel. In the semiconductor device A1, a first driving signal is inputted to the first semiconductor elements 11 in common, which are connected in parallel with each other, to operate the first semiconductor elements 11 in parallel.

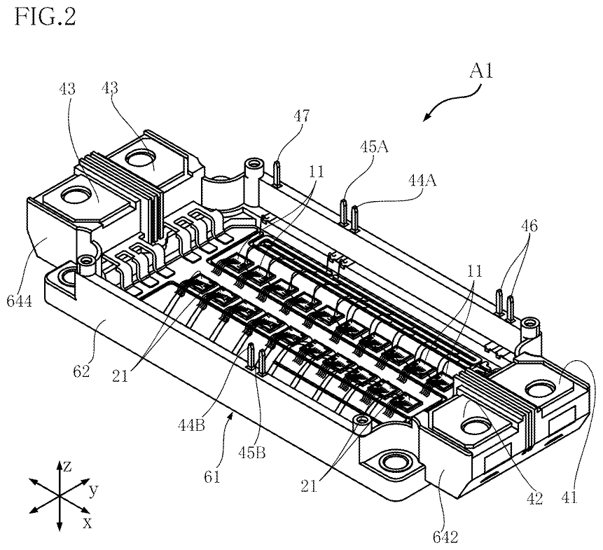

As shown in FIGS. 2, 4 and 9, the first semiconductor elements 11 are arranged along the first direction x. Each first semiconductor element 11 is joined to the power wiring part 311 via a conductive bonding material. The conductive bonding material is solder, metal paste material, or sintering metal etc.

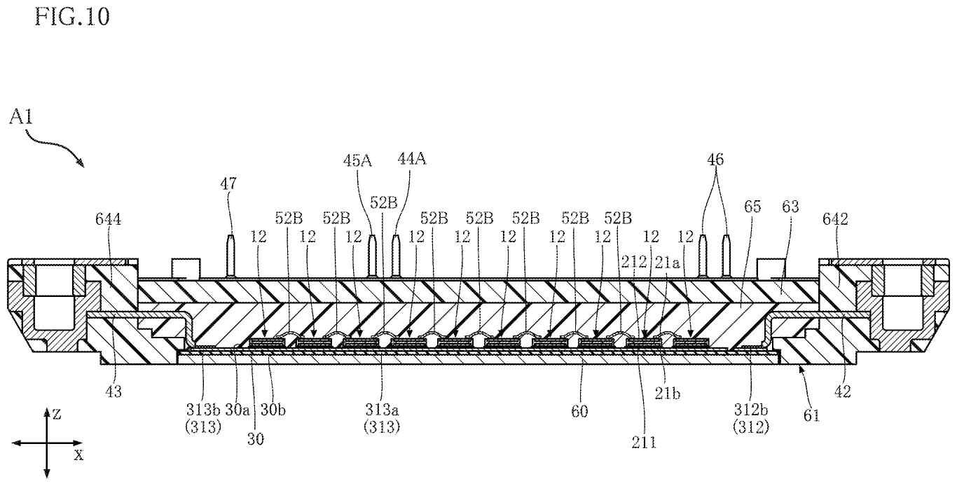

As shown in FIGS. 10 and 13, each second semiconductor element 21 has a second element obverse face 21a and a second element reverse face 21b. The second element obverse face 21a and the second element reverse face 21b are spaced apart from each other in the thickness direction z. The second element obverse face 21a faces one side (upside) of the thickness direction z, while the second element reverse face 21b faces the other side (downside) of the thickness direction z.

As shown in FIGS. 5, 6, 10 and 13, each second semiconductor element 21 has a fourth electrode 211, a fifth electrode 212, and a sixth electrode 213. In an example where each second semiconductor element 21 is a MOSFET, the fourth electrode 211 is a drain electrode, the fifth electrode 212 is a source electrode, and the sixth electrode 213 is a gate electrode. In each second semiconductor element 21, the fourth electrode 211 is, as shown in FIGS. 10 and 13, disposed on the second element reverse face 21b, while the fifth electrode 212 and the sixth electrode 213 are, as understood from FIGS. 5, 6, 10 and 13, disposed on the second element obverse face 21a.

A second driving signal (e.g. a gate voltage) is inputted to the sixth electrode 213 (the gate electrode) of each second semiconductor element 21. Each second semiconductor element 21 switches between a conducting state and an interrupting state depending on the inputted second driving signal. This operation between the conducting state and the interrupting state is referred to as a switching operation. A current flows from the fourth electrode 211 (the drain electrode) to the fifth electrode 212 (the source electrode) in the conducting state, while the current does not flow in interrupting state. In other word, the second driving signal (e.g. a gate voltage), which is inputted to the sixth electrode 213 (the gate electrode), controls on/off between the fourth electrode 211 (the drain electrode) and the fifth electrode 212 (the source electrode) in each second semiconductor element 21. A switching frequency of each semiconductor element 21 depends on the frequency of the second driving signal.

The plurality of second semiconductor elements 21 have a configuration as described in detail below, such that the fourth electrodes 211 (the drain electrode) are electrically connected to each other, and the fifth electrodes 212 (the source electrodes) are electrically connected to each other. As a result, the second semiconductor elements 21 are electrically connected in parallel. In the semiconductor device A1, a second driving signal is inputted to the second semiconductor elements 21 in common, which are connected in parallel with each other, to operate the second semiconductor elements 21 in parallel.

As shown in FIGS. 2, 4 and 10, the second semiconductor elements 21 are arranged along the first direction x. Each second semiconductor element 21 is joined to the power wiring part 313 via a conductive bonding material. The conductive bonding material is solder, metal paste material, or sintering metal etc.

The heat dissipation plate 60 is a rectangular flat plate in plan view, for example. The heat dissipation plate 60 is made of a high heat conductivity material such as copper or copper alloy. The heat dissipation plate 60 may be plated with Ni on its surface. The heat dissipation plate 60 is, as necessary, provided with a cooling member (e.g. heatsink) on its surface at the downside of the thickness direction z. As shown in FIGS. 9, 10 and 13, the insulating substrate 30 is mounted on the heat dissipation plate 60.

As understood from FIGS. 1-4, 9, 10 and 13, the case 61 has a cuboid-like external shape, for example. The case 61 is made of synthetic resin with electrical insulation and high heat resistance such as PPS (polyphenylene sulfide). In plan view, the case 61 is rectangular and has approximately the same size as the heat dissipation plate 60. As shown in FIGS. 1-4 and 7-13, the case 61 includes a frame part 62, a top plate 63, and a plurality of terminal pedestals 641-644.

The frame part 62 is secured on the surface of the heat dissipation plate 60 at the upside of the thickness direction z. The top plate 63 is secured to the frame part 62. As shown in FIGS. 1, 3, 9, 10 and 13, the top plate 63 closes an opening of the frame part 62 at the upside of the thickness direction z. As shown in FIGS. 9, 10 and 13, the top plate 63 faces the heat dissipation plate 60, which closes the downside of the frame part 62 in the thickness direction z. The top plate 63, the heat dissipation plate 60, and the frame part 62 define a circuit housing space (a space that houses the first semiconductor elements 11, the second semiconductor elements 21 etc.) in the case 61. The circuit housing space may be referred to as the inside of the case 61.

Two terminal pedestals 641 and 642 are disposed on one side of the frame part 62 in the first direction x, and are formed integral with the frame part 62. Two terminal pedestals 643 and 644 are disposed on the other side of the frame part 62 in the first direction x, and are formed integral with the frame part 62. Two terminal pedestals 641 and 642 are disposed along the second direction y on the side face of the frame part 62 at one side of the first direction x. The terminal pedestal 641 covers a part of the power terminal 41, and a part of the power terminal 41 is disposed on the surface of terminal pedestal 641 at the upside of the thickness direction z. The terminal pedestal 642 covers a part of the power terminal 42, and a part of the power terminal 42 is disposed on the surface of terminal pedestal 642 at the upside of the thickness direction z. Two terminal pedestals 643 and 644 are disposed along the second direction y on the side face of the frame part 62 at the other side of the first direction x. The terminal pedestal 643 covers a part of one of two power terminals 43, and a part of this power terminal 43 is disposed on the surface of terminal pedestal 643 at the upside of the thickness direction z. The terminal pedestal 644 covers a part of the other power terminal 43, and a part of this power terminal 43 is disposed on the surface of terminal pedestal 644 at the upside of the thickness direction z.

As shown in FIGS. 9, 10 and 13, the resin member 65 is filled in the area surrounded by the top plate 63, the heat dissipation plate 60, and the frame part 62 (the circuit housing space). The resin member 65 covers the first semiconductor elements 11, the second semiconductor elements 21 etc. The resin member 65 is made of black epoxy resin, for example. The constituent material of the resin member 65 is not limited to epoxy resin, but may be other insulating materials such as silicone gel. The resin member 65 may not be provided for the semiconductor device A1.

The insulating substrate 30 has electrical insulation properties. The insulating substrate 30 is made of ceramic with high heat conductivity, for example. Such ceramic includes AlN (aluminum nitride), SiN (silicon nitride), Al₂O₃ (aluminum oxide). The insulating substrate 30 is a flat plate, for example.

As shown in FIGS. 9, 10 and 13, the insulating substrate 30 has an obverse face 30a and a reverse face 30b. The obverse face 30a and the reverse face 30b are spaced apart from each other in the thickness direction. The obverse face 30a faces one side (upside) of the thickness direction z, while the reverse face 30b faces the other side (downside) of the thickness direction z. The first semiconductor elements 11 and the second semiconductor elements 21 are disposed on the obverse face 30a. The reverse face 30b faces the heat dissipation plate 60.

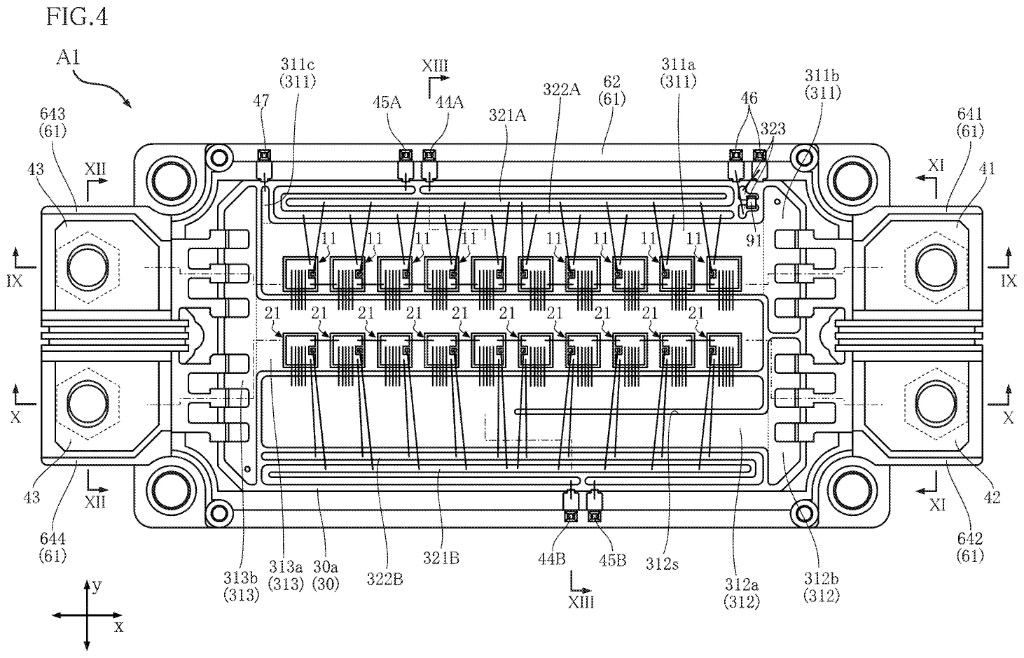

As shown in FIGS. 4, 9, 10 and 13, the plurality of power wiring parts 311-313 and the plurality of signal wiring parts 321A, 321B, 322A, 322B and 323 are formed on the obverse face 30a of the insulating substrate 30. Each of the power wiring parts 311-313 and signal wiring parts 321A, 321B, 322A, 322B and 323 is a metal layer, for example. The metal layer may be made of copper or copper alloy, or alternatively aluminum or aluminum alloy. The power wiring parts 311-313 and the signal wiring parts 321A, 321B, 322A, 322B and 323 are spaced apart from each other.

The power wiring parts 311, 312 and 313 provide a conduction path for main current in the semiconductor device A1.

The power wiring part 311 electrically conducts to the first electrodes 111 (the drain electrodes) of the first semiconductor elements 11. The power wiring part 311 electrically conducts to the power terminal 41. The power wiring part 311 includes two pad parts 311a and 311b and an extending part 311c. The two pad parts 311a and 311b and the extending part 311c are connected with each other so as to be an integral member.

As shown in FIGS. 4-6, 9 and 13, the first semiconductor elements 11 are jointed to the pad part 311a, which is electrically connected to the first electrodes 111 (the drain electrodes) of the first semiconductor elements 11. The pad part 311a extends from the pad part 311b along the first direction x. In plan view, the pad part 311a may have a band-like shape whose longitudinal direction corresponds to the first direction x. On the pad part 311a, the first semiconductor elements 11 are arranged along the first direction x.

As shown in FIGS. 4, 5 and 9, the power terminal 41 is jointed to the pad part 311b. In plan view, the pad part 311b has a band-like shape whose longitudinal direction corresponds to the second direction y. In the first direction x, the pad part 311b is connected to one end of the pad part 311a (where the power terminal 41 is disposed).

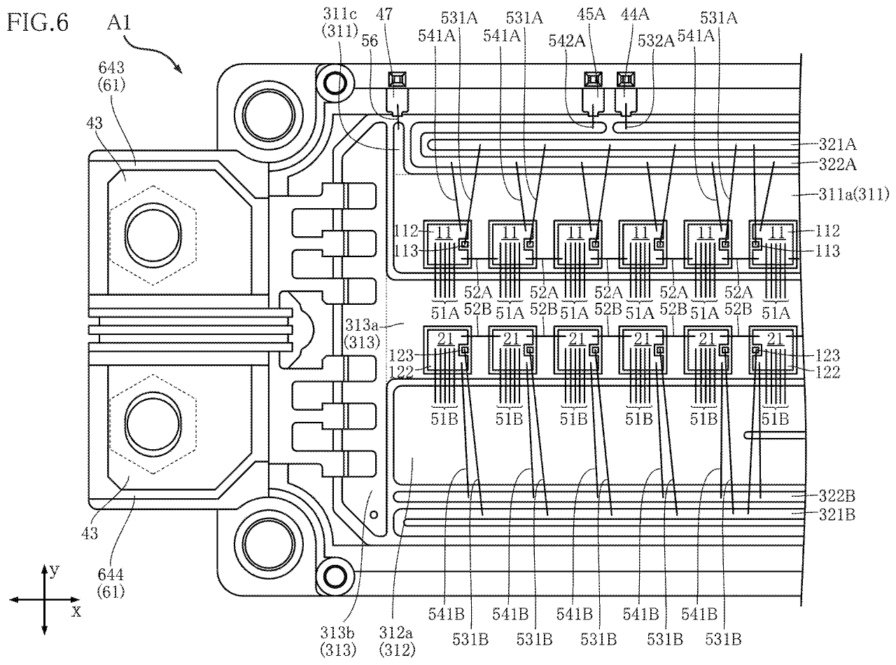

As shown in FIGS. 4 and 6, the extending part 311c extends in the second direction y from the other end of the pad part 311a in the first direction x (the end opposite to where the power terminal 41 is provided). In the example shown in FIGS. 4 and 6, the extending part 311c is positioned between the power wiring part 312 (a pad part 312b described below) and two signal wiring part 321A and 322A in plan view.

The power wiring part 312 electrically conducts to the fifth electrodes 212 (the source electrodes) of the second semiconductor elements 21. The power wiring part 312 electrically conducts to the power terminal 42. The power wiring part 312 includes two pad parts 312a and 312b. Two pad parts 312a and 312b are connected with each other so as to be an integral member.

As shown in FIGS. 5, 6 and 13, the connection members 51B are jointed to the pad part 312a, which is electrically connected to the fifth electrodes 212 (the source electrodes) of the second semiconductor elements 21 via the connection members 51B. The pad part 312a extends from the pad part 312b along the first direction x. In plan view, the pad part 312a may have a band-like shape whose longitudinal direction corresponds to the first direction x. The pad part 312a is positioned on the other side relative to the pad part 311a in the second direction y (the downside in FIG. 4). The pad part 312a is parallel (or substantially parallel) to the pad part 311a.

As shown in FIGS. 4 and 5, the pad part 312a is formed with a slit 312s. In plan view, the slit 312s extends along the first direction, having a base end adjacent to the relevant end of the pad part 312a in the first direction x (where the pad part 312b is disposed). The slit 312s has a front end that is located at the center of the pad part 312a in the first direction x.

As shown in FIGS. 4, 5 and 10, the power terminal 42 is joined to the pad part 312b. In plan view, the pad part 312b has a band-like shape whose longitudinal direction corresponds to the second direction y. In the first direction x, the pad part 312b is connected to one end of the pad part 312a (where the power terminal 42 is disposed). The pad part 312b is positioned on the other side relative to the pad part 311b in the second direction y (the downside in FIG. 4).

The power wiring part 313 electrically conducts to the second electrodes 112 (the source electrodes) of the first semiconductor elements 11 and also to the fourth electrodes 211 (the drain electrodes) of the second semiconductor elements 21. The power wiring part 313 electrically conducts to two power terminals 43. The power wiring part 313 includes two pad parts 313a and 313b. The two pad parts 313a and 313b are connected with each other so as to be an integral member.

As shown in FIGS. 5, 6 and 13, the connection members 51A are joined to the pad part 313a, which is electrically connected to the second electrodes 112 (the source electrodes) of the first semiconductor elements 11 via the connection members 51A. As shown in FIGS. 4-6, 10 and 13, the second semiconductor elements 21 are joined to the pad part 313a, which is electrically connected to the fourth electrodes 211 (the drain electrodes) of the second semiconductor elements 21. The pad part 313a extends from the pad part 313b along the first direction x. In plan view, the pad part 313a may have a band-like shape whose longitudinal direction corresponds to the first direction x. On the pad part 313a, the second semiconductor elements 21 are arranged along the first direction x. The pad part 313a is positioned between the pad part 311a and the pad part 312a in the second direction y. The pad part 313a is parallel (or substantially parallel) to the pad part 312a.

As shown in FIGS. 4, 6, 9 and 10, two power terminals 43 are joined to the pad part 313b. In plan view, the pad part 313b has a band-like shape whose longitudinal direction corresponds to the second direction y. In the first direction x, the pad part 313b is connected to the other end of the pad part 313a (where two power terminals 43 are disposed).

As shown in FIGS. 4-6, the connection members 531A are joined to the signal wiring part 321A, which is electrically connected to the third electrodes 113 (the gate electrodes) of the first semiconductor elements 11 via the connection members 531A. The signal wiring part 321A transmits the first driving signal. As shown in FIGS. 4-6, the connection members 531B are joined to the signal wiring part 321B, which is electrically connected to the sixth electrodes 213 (the gate electrodes) of the second semiconductor elements 21 via the connection members 531B. The signal wiring part 321B transmits the second driving signal. As shown in FIGS. 4-6, in the second direction y, the signal wiring part 321A and the signal wiring part 321B are opposingly positioned each other with the pad parts 311a, 312a and 313a sandwiched therebetween. In the second direction y, the signal wiring part 321A is opposite to the pad part 313a with respect to the pad part 311a, and the signal wiring part 321B is opposite to the pad part 313a with respect to the pad part 312a.

As shown in FIGS. 4-6, the connection members 541A are joined to the signal wiring part 322A, which is electrically connected to the second electrodes 112 (the source electrodes) of the first semiconductor elements 11 via the connection members 541A. The signal wiring part 322A transmits a first detecting signal. The first detecting signal indicates the conducting state of each first semiconductor element 11, which may be a voltage signal corresponding to the current (source current) flowing through each second electrode 112 (the source electrode). As shown in FIGS. 4-6, the connection members 541B are joined to the signal wiring part 322B, which is electrically connected to the fifth electrodes 212 (the source electrodes) of the second semiconductor elements 21 via the connection members 541B. The signal wiring part 322B transmits a second detecting signal. The second detecting signal indicates the conducting state of each second semiconductor element 21, which may be a voltage signal corresponding to the current (source current) flowing through each fifth electrode 212 (the source electrode). As shown in FIGS. 4-6, in the second direction y, the signal wiring part 322A and the signal wiring part 322B are opposingly positioned each other with the pad parts 311a, 312a and 313a sandwiched therebetween. In the second direction y, the signal wiring part 322A and the signal wiring part 321A are provided on the same side with respect to the pad part 311a. Further, in the second direction y, the signal wiring part 322B and the signal wiring part 321B are provided on the same side with respect to the pad part 312a.

As shown in FIGS. 4 and 5, the two signal wiring parts 323 are spaced apart from each other in the second direction y. A thermistor 91 is joined to each of the signal wiring parts 323. The thermistor 91 is disposed between the signal wiring parts 323. In an example different from the semiconductor device A1, the thermistor 91 may not be joined to the signal wiring parts 323. As shown in FIGS. 4 and 5, the signal wiring parts 323 are located near a corner of the insulating substrate 30. The paired signal wiring parts 323 are disposed between the pad part 311b and the two signal wiring parts 321A, 322A.

As shown in FIGS. 1 and 3, a part of each of the power terminals 41-43 and a part of each of the signal terminals 44A, 44B, 45A, 45B, 46 and 47 are exposed from the case 61. The constituent material of the power terminals 41-43 and the signal terminals 44A, 44B, 45A, 45B, 46, and 47 is copper or copper alloy, though not limited to this.

As shown in FIGS. 4, 5 and 9, the power terminal 41 is joined to the power wiring part 311 within the case 61. The power terminal 41 electrically conducts to the first electrodes 111 (the drain electrodes) of the first semiconductor elements 11 via the power wiring part 311.

As shown in FIGS. 4, 5 and 10, the power terminal 42 is joined to the power wiring part 312 within the case 61. The power terminal 42 electrically conducts to the fifth electrodes 212 (the source electrodes) of the second semiconductor elements 21 via the power wiring part 312.

As shown in FIGS. 4, 6, 9 and 10, the two power terminals 43 are joined to the power wiring part 313 within the case 61. The two power terminals 43 electrically conduct, via the power wiring part 313, to the second electrodes 112 (the source electrodes) of the first semiconductor elements 11, and also to the fourth electrodes 211 (the drain electrodes) of the second semiconductor elements 21.

The power terminal 41 and the power terminal 42 are connected to a power source, so that a source voltage (e.g. a direct voltage) is applied to these terminals. For example, the power terminal 41 is a positive electrode (a P terminal) and the power terminal 42 is a negative electrode (an N terminal). The power terminal 41 and the power terminal 42 are spaced apart from each other and arranged along the second direction y. The two power terminals 43 output a voltage that is power-converted by the switching operation of the first semiconductor elements 11 and the second semiconductor elements 21. The two power terminals 43 are a power output terminal (an OUT terminal). The two power terminals 43 are spaced apart from each other and arranged along the second direction y. In the first direction x, the power terminal 41 and the power terminal 42 are opposite to the two power terminals 43 with respect to the insulating substrate 30. In a different configuration from the semiconductor device A1, the number of the power terminals 43 is not two, but may be one. In this case, the single power terminal 43 may be disposed at the side face of the frame part 62 that is offset to the one side of the first direction x than the other side face and located at the center of the first-mentioned side face in the second direction y. The main current in the semiconductor device A1 is generated from the source voltage and the power-converted voltage described above.

As shown in FIG. 6, the connection member 532A is joined to the signal terminal 44A, which electrically conducts to the signal wiring part 321A via the connection member 532A. The signal wiring part 321A electrically conducts to the third electrodes 113 (the gate electrodes) of the first semiconductor elements 11, and hence the signal terminal 44A electrically conducts to the third electrodes 113 (the gate electrodes) of the first semiconductor elements 11. The signal terminal 44A is an input terminal of the first driving signal.

As shown in FIG. 5, the connection member 532B is joined to the signal terminal 44B, which electrically conducts to the signal wiring part 321B via the connection member 532B. The signal wiring part 321B electrically conducts to the sixth electrodes 213 (the gate electrodes) of the second semiconductor elements 21, and hence the signal terminal 44B electrically conducts to the sixth electrodes 213 (the gate electrodes) of the second semiconductor elements 21. The signal terminal 44B is an input terminal of the second driving signal.

As shown in FIG. 6, the connection member 542A is joined to the signal terminal 45A, which electrically conducts to the signal wiring part 322A via the connection member 542A. The signal wiring part 322A electrically conducts to the second electrodes 112 (the source electrodes) of the first semiconductor elements 11, and hence the signal terminal 45A electrically conducts to the second electrodes 112 (the source electrodes) of the first semiconductor elements 11. The signal terminal 45A is an output terminal of the first detecting signal.

As shown in FIG. 5, the connection member 542B is joined to the signal terminal 45B, which electrically conducts to the signal wiring part 322B via the connection member 542B. The signal wiring part 322B electrically conducts to the fifth electrodes 212 (the source electrodes) of the second semiconductor elements 21, and hence the signal terminal 45B electrically conducts to the fifth electrodes 212 (the source electrodes) of the second semiconductor elements 21. The signal terminal 45B is an output terminal of the second detecting signal.

As shown in FIG. 5, the pair of connection members 55 are joined to the respective signal terminals 46, which electrically conduct to the respective signal wiring parts 323 via the respective connection members 55. Hence, the signal terminals 46 electrically conduct to the thermistor 91. The signal terminals 46 are a terminal for detecting the temperature of the inside of the case 61. If the thermistor 91 is not joined to signal wiring parts 323, the signal terminals 46 may be a non-connect terminal.

As shown in FIG. 6, the connection member 56 is joined to the signal terminal 47, which electrically conducts to the power wiring part 311 via the connection terminal 56. Hence, the signal terminal 47 electrically conducts to the first electrodes 111 (the drain electrodes) of the first semiconductor elements 11. The signal terminal 47 is an output terminal of a third detecting signal. The third detecting signal is used for detecting the voltage applied to the power wiring part 311.

Each of the plurality of connection members 51A, 51B, 52A, 52B, 531A, 531B, 532A, 532B, 541A, 541B, 542A, 542B, 55 and 56 electrically connect two parts that are spaced apart from each other. In the semiconductor element A1, each of the connection members 51A, 51B, 52A, 52B, 531A, 531B, 532A, 532B, 541A, 541B, 542A, 542B, 55 and 56 is a bonding wire(s). The constituent material of each of the connection members 51A, 51B, 52A, 52B, 531A, 531B, 532A, 532B, 541A, 541B, 542A, 542B, 55, 56 may be gold, copper, or aluminum.

As shown in FIGS. 4-6 and 13, each of the connection members 51A is joined to the second electrode 112 (the source electrode) of the relevant first semiconductor element 11 and the pad part 313a, thereby electrically connecting the second electrode 112 and the power wiring part 313 to each other. In the semiconductor device A1, as shown in FIGS. 5 and 6, a plurality of connection members 51A are joined to any one of the second electrodes 112. The main current of the semiconductor device A1 flows through the connection members 51A. In the semiconductor device A1, the connection members 51A are not limited to bonding wires, but may be metal (e.g., copper) plate members. In this case, one connection member 51A may be sufficient for joining a second electrode 112 and the pad part 313a.

As shown in FIGS. 4-6 and 13, each of the connection members 51B is joined to the fifth electrode 212 (the source electrode) of the relevant second semiconductor element 21 and the pad part 312a, thereby electrically conducting the fifth electrode 212 and the power wiring part 312 to each other. In the semiconductor device A1, as shown in FIGS. 5 and 6, a plurality of connection members 51B are joined to any one of the fifth electrodes 212. The main current of the semiconductor device A1 flows through the connection members 51B. In the semiconductor device A1, the connection members 51B are not limited to bonding wires, but may be metal (e.g., copper) plate members. In this case, one connection member 51B may be sufficient for joining a fifth electrode 212 and the pad part 312a.

As shown in FIGS. 5, 6 and 9, each of the connection members 52A is joined to the second electrodes 112 (the source electrodes) of two first semiconductor elements 11 adjacent in the first direction x, thereby electrically connecting these second electrodes 112. In plan view, each of the connection members 52A extends along the first direction x.

As shown in FIGS. 5, 6 and 10, each of the connection members 52B is joined to the fifth electrodes 212 (the source electrodes) of two second semiconductor elements 21 adjacent in the first direction x, thereby electrically connecting these fifth electrodes 212. In plan view, each of the connection members 52B extends along the first direction x.

As shown in FIGS. 5 and 6, each of the connection members 531A is joined to the third electrode 113 (the gate electrode) of the relevant first semiconductor element 11 and the signal wiring part 321A, thereby electrically connecting the third electrode 113 and the signal wiring part 321A to each other. As shown in FIGS. 5 and 6, the connection member 532A is joined to the signal wiring part 321A and the signal terminal 44A, thereby electrically connecting them. Thus, the signal terminal 44A electrically conducts to the third electrodes 113 of the first semiconductor elements 11 via the connection member 532A, the signal wiring part 321A, and the connection members 531A.

As shown in FIGS. 5 and 6, each of the connection members 531B is joined to the sixth electrode 213 (the gate electrode) of the relevant second semiconductor element 21 and the signal wiring part 321B, thereby electrically connecting the sixth electrode 213 and the signal wiring part 321B to each other. As shown in FIGS. 5 and 6, the connection member 532B is joined to the signal wiring part 321B and the signal terminal 44B, thereby electrically connecting them. Thus, the signal terminal 44B electrically conducts to the sixth electrodes 213 of the second semiconductor elements 21 via the connection member 532B, the signal wiring part 321B, and the connection members 531B.

As shown in FIGS. 5 and 6, each of the connection members 541A is joined to the second electrode 112 (the source electrode) of the relevant first semiconductor element 11 and the signal wiring part 322A, thereby electrically connecting the second electrodes 112 and the signal wiring part 322A to each other. As shown in FIGS. 5 and 6, the connection member 542A is joined to the signal wiring part 322A and the signal terminal 45A, thereby electrically connecting them. Thus, the signal terminal 45A electrically conducts to the second electrodes 112 of the first semiconductor elements 11 via the connection member 542A, the signal wiring part 322A, and the connection members 541A.

As shown in FIGS. 5 and 6, each of the connection members 541B is joined to the fifth electrode 212 (the source electrode) of the relevant second semiconductor element 21 and the signal wiring part 322B, thereby electrically connecting the fifth electrode 212 and the signal wiring part 322B to each other. As shown in FIGS. 5 and 6, the connection member 542B is joined to the signal wiring part 322B and the signal terminal 45B, thereby electrically connecting them. Thus, the signal terminal 45B electrically conducts to the fifth electrodes 212 of the second semiconductor elements 21 via the connection member 432B, the signal wiring part 322B, and the connection members 541B.

As shown in FIG. 5, the two connection members 55 are joined to the two signal wiring parts 323 and the two signal terminals 46, respectively, thereby electrically connecting these pairs, respectively. Hence, the signal terminals 46 electrically conduct to the thermistor 91 via the connection members 55 and the signal wiring parts 323. If the thermistor 91 is not to be joined to the signal wiring parts 323, the connection members 55 may not be required.

As shown in FIG. 5, the connection member 56 is joined to the extending part 311c and the signal terminal 47, thereby electrically connecting the power wiring part 311 and the signal terminal 47. Hence, the signal terminal 47 electrically conducts to the first electrodes 111 (the drain electrodes) of the first semiconductor elements 11 via the connection member 56 and the power wiring part 311.

An effect of the semiconductor device A1 may be as follows.

The semiconductor device A1 includes the semiconductor elements 11, which are connected in parallel. The semiconductor device A1 also includes first conductors and second conductors, where each of the first conductors and the second conductors is electrically interposed between two second electrodes 112 (source electrodes) of two first semiconductor elements 11 adjacent in the first direction x. Thus, each of the first conductors and the second conductors provides conduction path extending between two second electrodes 112 for electrically connecting the two second electrodes 112 to each other. In the semiconductor device A1, each first conductor is formed by: the connection members 51A joined to the two second electrode 112 of one of the first semiconductor elements 11; the connection members 51A joined to the second electrode 112 of the other of the first semiconductor elements 11; and the portion of the pad part 313a (power wiring part 313) between the connected portions of the respective connecting members 51A. Each second conductor is formed by the connection member 52A directly connected to the second electrodes 112 of the respective first semiconductor elements 11. With any two first semiconductor elements 11 adjacent in the first direction x, their second electrodes 112 are electrically connected to each other via a first conduction path provided by the first conductor and a second conduction path provided by the second conductor. The first conduction path is a path between the second electrodes 112 that conducts when the main current path is formed. The first conduction path and the second conduction path are at least partially in parallel with each other, and the combined inductance of the first conduction path and the second conduction path is smaller than the inductance of the first conduction path. Such configuration reduces the inductance between the second electrodes 112 (the source electrodes) of any two first semiconductor elements 11 adjacent in the first direction x by the presence of the second conduction path that is at least partially in parallel with the first conduction path provided when the main current path is formed. In other word, the semiconductor device A1 can reduce the inductance between the second electrodes 112 (the source electrodes) compared to the configuration without the second conduction path. Through the study by the inventors, it has been found that when operating two first semiconductor elements 11 in parallel, a smaller inductance between the two second electrodes (the source electrodes) can prevent the occurrence of resonance phenomenon. Thus, the semiconductor device A1 is advantageous to suppressing the resonance phenomenon when the first semiconductor elements 11 are operated in parallel.

In the semiconductor device A1, the inductance of the second conduction path is smaller than the inductance of the first conduction path. As the first conduction path and the second conduction path are in parallel in the semiconductor device A1, a smaller inductance of the second conduction path reduces the combined inductance of the first conduction path and the second conduction path, provided that the inductance of the first conduction path remains the same. In other words, provided that the inductance of the first conduction path is constant, the smaller inductance of the second conduction path reduces the ratio of the combined inductance relative to that of the first conduction path. Thus, the semiconductor device A1 is advantageous in reducing the inductance between the second electrodes 112.

In the semiconductor device A1, the second conduction path is shorter than the first conduction path. Inductance varies depending on the material, shape, and size (e.g., length, diameter and thickness) of a conductor. For example, shortening the length results in a smaller inductance. Thus, the semiconductor device A1 is advantageous in reducing the inductance of the second conduction path than the inductance of the first conduction path.

In the semiconductor device A1, each connection member 52A is directly joined to the second electrodes 112 of two first semiconductor elements 11 adjacent in the first direction x. This configuration can shorten the length of the first conduction path than the length of the second conduction path in electrically connecting the second electrodes 112 of the two first semiconductor elements 11 adjacent in the first direction x.

The semiconductor device A1 includes the second semiconductor elements 21, which are connected in parallel. The semiconductor device A1 also includes third conductors and fourth conductors, where each of the third conductors and the fourth conductors is electrically interposed between two fifth electrodes 212 (source electrodes) of two second semiconductor elements 21 adjacent in the first direction x. In the semiconductor device A1, each third conductor is formed by: the connection members 51B joined to the fifth electrode 212 of one of the second semiconductor elements 21; the connection members 51B joined to the fifth electrode 212 of the other of the second semiconductor elements 21; and the portion of the pad part 312a (power wiring part 312) between the connected portions of the connection members 51B. Each fourth conductor is formed by the connection member 52B directly connected to the fifth electrodes 212 of the respective second semiconductor elements 21. With any two second semiconductor elements 21 adjacent in the first direction x, their fifth electrodes 212 are electrically connected to each other via a third conduction path provided by the third conductor and a fourth conduction path provided by the fourth conductor. The third conduction path is a path between the fifth electrodes 212 that conducts when the main current path is formed. The third conduction path and the fourth conduction path are at least partially in parallel with each other, and the combined inductance of the third conduction path and the fourth conduction path is smaller than the inductance of the third conduction path. Such configuration reduces the inductance between the fifth electrodes 212 (the source electrodes) of any two second semiconductor elements 21 adjacent in the first direction x by the presence of and the fourth conduction path that is at least partially in parallel with the third conduction path, provided when the main current path is formed. In other words, the semiconductor device A1 can reduce the inductance between the fifth electrodes 212 (the source electrodes) compared to the configuration without the fourth conduction path. Thus, the semiconductor device A1 is advantageous in suppressing the resonance phenomenon when operating the second semiconductor elements 21 in parallel, as when operating the first semiconductor elements 11 in parallel.

In the semiconductor device A1, the inductance of the fourth conduction path is smaller than the inductance of the third conduction path. As the third conduction path and the fourth conduction path are in parallel in the semiconductor device A1, a smaller inductance of the fourth conduction path reduces the combined inductance of the third conduction path and the fourth conduction path, provided that the inductance of the third conduction path remains the same. In other words, provided that the inductance of the third conduction path is constant, the smaller inductance of the fourth conduction path reduces the ratio of the combined inductance relative to that of the third conduction path. Thus, the semiconductor device A1 is advantageous in reducing the inductance between the fifth electrodes 212.

In the semiconductor device A1, the fourth conduction path is shorter than the third conduction path. Thus, the semiconductor device A1 is advantageous in reducing the inductance of the fourth conduction path than the inductance of the third conduction path.

In the semiconductor device A1, each connection member 52B is directly joined to the fifth electrodes 212 of two second semiconductor elements 21 adjacent in the first direction x. This configuration can shorten the length of the third conduction path than the length of the fourth conduction path in electrically connecting the fifth electrodes 212 of the two second semiconductor elements 21 adjacent in the first direction x.

In the semiconductor device A1, the connection members 52A may be metal (e.g., copper) plate members instead of bonding wires. In this case, the inductance of the connection members 52A may be reduced, so that the inductance of the second conduction path is further reduced. Similarly, the connection members 52B may be metal (e.g., copper) plate members instead of bonding wires. In this case, the inductance of the connection members 52B may be reduced, so that the inductance of the fourth conduction path is further reduced.

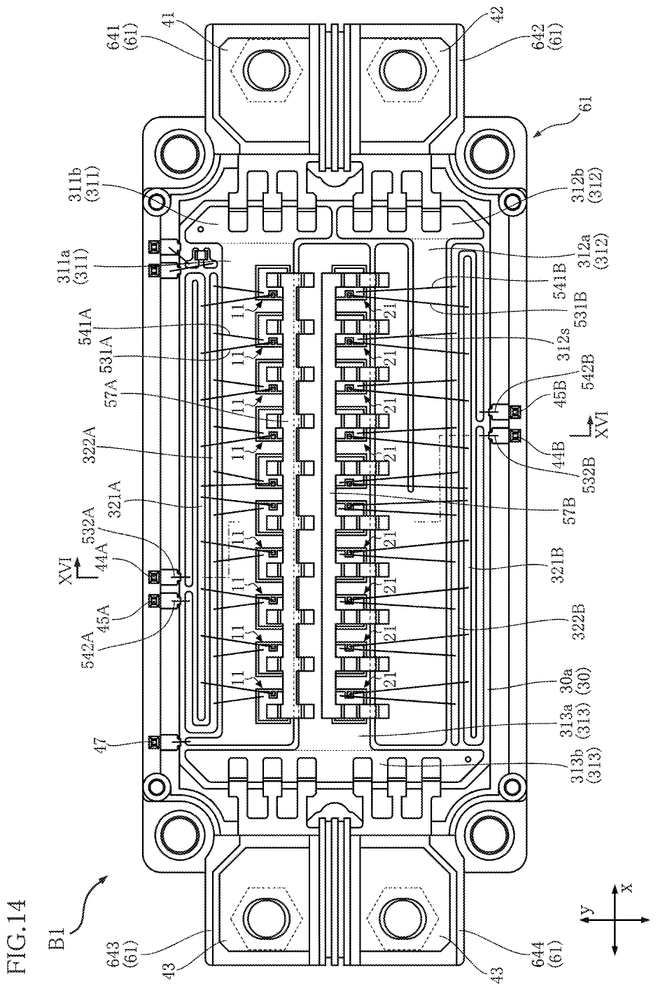

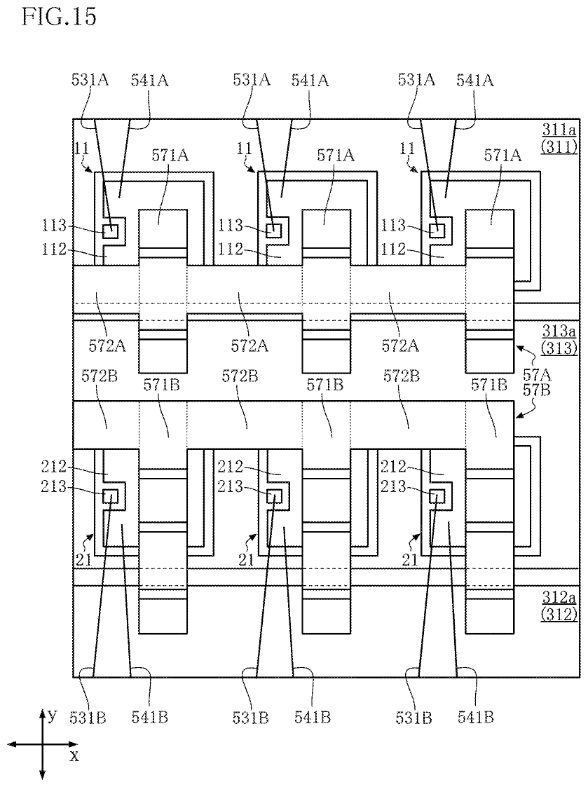

FIGS. 14-16 show a semiconductor device B1 according to a second embodiment. The semiconductor device B1 differs from the semiconductor device A1 in following configurations. First, the semiconductor device B1 includes a connection member 57A instead of the connection members 51A and 52A. Second, the semiconductor device B1 includes a connection member 57B instead of the connection members 51B and 52B.

Two connection members 57A and 57B are plate members made of a metal material. The metal material may be copper or a copper alloy, but not limited to this.

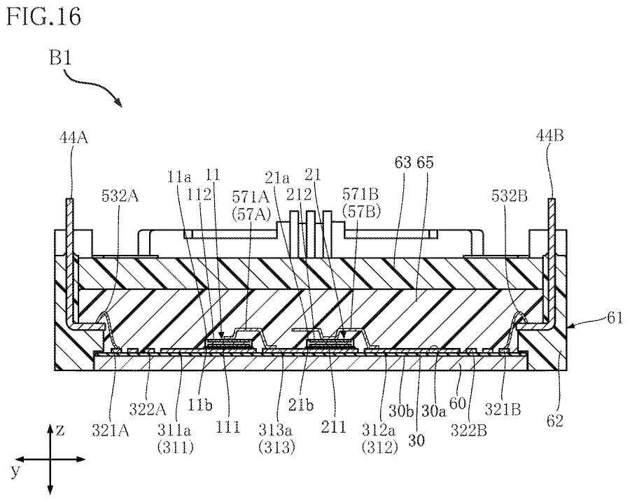

As shown in FIGS. 14 and 15, the connection member 57A includes band-shaped parts 571A and linking parts 572A. In the same way as the connection members 51A, each band-shaped part 571A is joined to the second electrode 112 (the source electrode) of the first semiconductor element 11 and the pad part 313a (the power wiring part 313), thereby electrically connecting them. In plan view, each band-shaped part 571A has a band-like shape whose longitudinal axis corresponds to the second direction y. As shown in FIG. 16, each band-shaped part 571A is partially bent. Each linking part 572A is sandwiched between two band-shaped parts 571A adjacent in the first direction x, and is connected to them. In the example shown in FIGS. 14 and 15, in the band-shaped part 571A, each linking part 572A is connected to the interposed portion between the portion jointed to the second electrode 112 and the portion jointed to the pad part 313a. The band-shaped parts 571A conduct to each other via the linking parts 572A.

As shown in FIGS. 14 and 15, the connection member 57B includes band-shaped parts 571B and linking parts 572B. In the same way as the connection members 51B, each band-shaped part 571B is joined to the third electrode 212 (the source electrode) of the second semiconductor element 21 and the pad part 312a (power wiring part 312), thereby electrically connecting them. In plan view, each band-shaped part 571B has a band-like shape whose longitudinal axis corresponds to the second direction y. As shown in FIG. 16, each band-shaped part 571B is partially bent. Each linking part 572B is sandwiched between two band-shaped parts 571B adjacent in the first direction x, and is connected to them. The band-shaped parts 571B electrically conduct to each other via the linking parts 572B. In the example shown in FIGS. 14 and 15, in plan view, each band-shaped part 571B extends from the portion jointed to the fifth electrode 212 in the opposite senses of the second direction y. Each linking part 572B is connected to a portion of a relevant band-shaped part 571B that is opposite to the portion jointed to the pad part 312a with respect to the intermediate portion jointed to the fifth electrode 212. In this example, in the band-shaped part 571B, the dimension in the second direction y from the portion joined to the fifth electrode 212 to the portion connected to the linking part 572B is smaller than the dimension in the second direction y from the portion joined to the fifth electrode 212 to the portion joined to the pad part 312a.

An effect of the semiconductor device B1 may be as follows.

The semiconductor device B1 includes first conductors and second conductors, as with the semiconductor device A1. In the semiconductor device B1, each first conductor is formed by: the band-shaped part 571A joined to the second electrode 112 of one of the first semiconductor elements 11; the band-shaped part 571A joined to the second electrode 112 of the other of the first semiconductor elements 11; and the portion of the pad part 313a (power wiring part 313) interposed between the connected portions of the respective band-shaped part 571A. Each second conductor is formed by: the linking part 572A; and the portions of the two respective band-shaped parts 571A, each of which extends from the second electrode 112 to the linking part 572A. With any two first semiconductor elements 11 adjacent in the first direction x, their second electrodes 112 (the source electrodes) are electrically connected to each other via a first conduction path provided by the first conductor and a second conduction path provided by the second conductor. In the semiconductor device B1, the first conduction path is a path between the second electrodes 112 that conducts when the main current path is formed, as with the semiconductor device A1. The first conduction path and the second conduction path are at least partially in parallel with each other, and the combined inductance of the first conduction path and the second conduction path is smaller than the inductance of the first conduction path. Such configuration reduces the inductance between the second electrodes 112 (the source electrodes) of any two first semiconductor elements 11 adjacent in the first direction x by the presence of and the second conduction path. Thus, the semiconductor device B1 is advantageous in suppressing the resonance phenomenon when the first semiconductor elements 11 are operated in parallel.

In the semiconductor device B1, the connection member 57A includes linking parts 572A each connected to two adjacent band-shaped parts 571A. Each linking part 572A is connected to the interposed portion of a relevant band-shaped part 571A between the portions joined to the second electrode 112 and the pad portion 313a. Such configuration can shorten the length of the second conduction path than the length of the first conduction path in electrically connecting the second electrodes 112 of the two first semiconductor elements 11. Further, in the semiconductor device B1, the second conduction path is shorter than the first conduction path, so that the inductance of the second conduction path can be reduced than the inductance of the first conduction path.

The semiconductor device B1 includes third conductors and fourth conductors, as with the semiconductor device A1. In the semiconductor device B1, each third conductor is formed by: the band-shaped part 571B joined to the fifth electrode 212 of one of the second semiconductor elements 21; the band-shaped part 571B joined to the fifth electrode 212 of the other of the second semiconductor elements 21; and the portion of the pad part 312a (power wiring part 312) interposed between the connected portions of the respective band-shaped parts 571B. Each fourth conductor is formed by: the linking part 572B; and the portions of the two band-shaped parts 571B, each of which extends from the fifth electrode 212 to the linking part 572B. With any two second semiconductor elements 21 adjacent in the first direction x, their fifth electrodes 212 (the source electrodes) are electrically connected to each other via a third conduction path provided by the third conductor and a fourth conduction path provided by the fourth conductor. In the semiconductor device B1, the third conduction path is a path between fifth electrodes 212 that conducts when the main current path is formed, as with the semiconductor device A1. The third conduction path and the fourth conduction path are at least partially in parallel with each other, and the combined inductance of the third conduction path and the fourth conduction path is smaller than the inductance of the third conduction path. Such configuration reduces the inductance between the fifth electrodes 212 (the source electrodes) of any two second semiconductor elements 21 by the presence of the fourth conduction path. Thus, the semiconductor device B1 is advantageous in suppressing the resonance phenomenon when the second semiconductor elements 21 are operated in parallel.

In the semiconductor device B1, the connection member 57B includes linking parts 572B each connected to two adjacent band-shaped parts 571B. In each band-shaped part 571B, the dimension in the second direction y between the part joined to the fifth electrode 212 and the portion connected to the linking part 572B is smaller than the part joined to the fifth electrode 212 and the portion joined to the pad part 312a. Such configuration can shorten the length of the fourth conduction path than the length of the third conduction path in electrically connecting the fifth electrodes 212 of the two second semiconductor elements 21. Further, in the semiconductor device B1, the fourth conduction path is shorter than the third conduction path, so that the inductance of the fourth conduction path can be reduced than the inductance of the third conduction path.

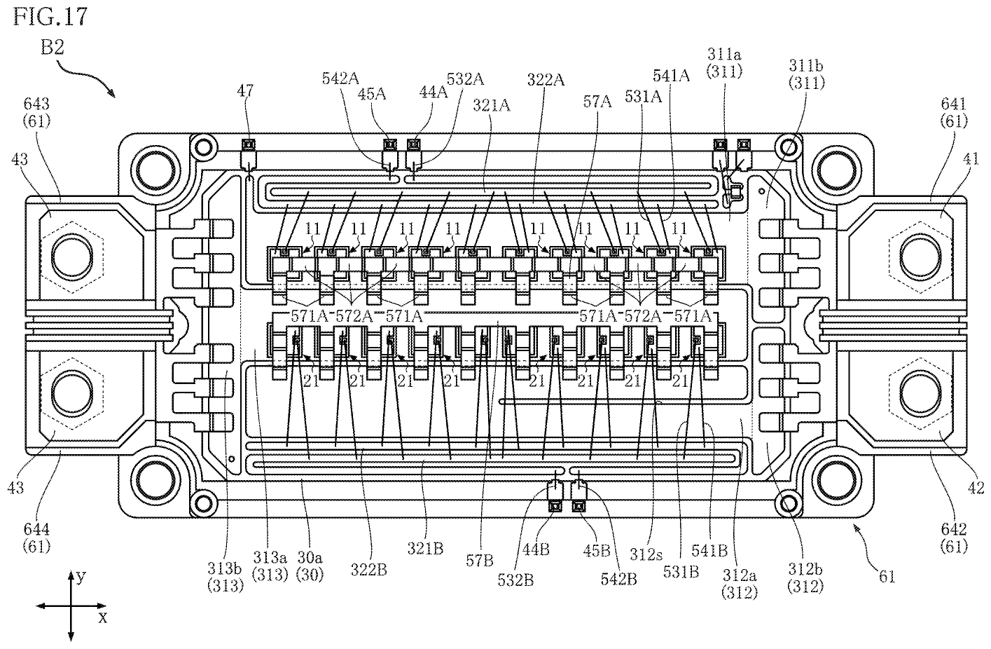

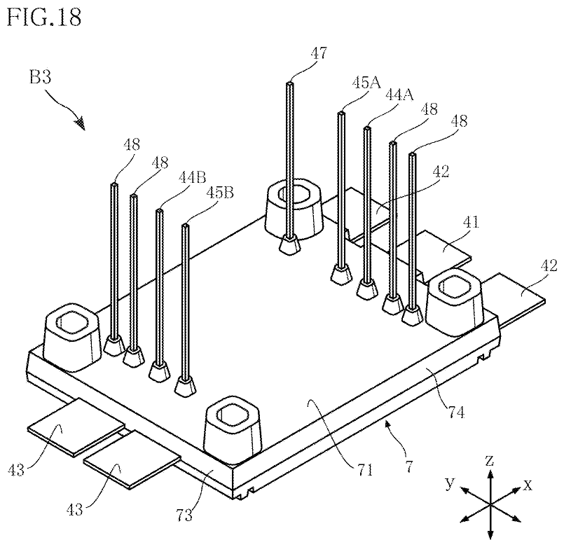

FIG. 17 shows a semiconductor device B2 according to a first variant of the second embodiment. The semiconductor device B2 differs from the semiconductor device B1 in the shape of the connection member 57A.

In the connection member 57A of the semiconductor device B2, each linking part 572A connects to the portion of the band-shaped parts 571A overlapping with the respective first semiconductor elements 11 in plan view (the portion joined to the second electrode 112). This configuration results in the placement of the third electrodes 113 of the first semiconductor elements 11 in the one side of the second direction y (the side at which signal wiring part 321A is disposed) in plan view. Each third electrode 113 does not overlap with the connection member 57A in plan view, allowing wire bonding to the third electrodes 113.

The semiconductor device B2 achieves the same effect as the semiconductor device B1. Further, the semiconductor device B2 has the second conduction path, which is the conduction path via the relevant linking part 572A, shorter than that of the semiconductor device B1, thereby reducing the inductance of the second conduction path compared to the semiconductor device B1. Thus, the semiconductor device B2 is advantageous over the semiconductor device B1 in suppressing the resonance phenomenon when the first semiconductor elements 11 are operated in parallel.

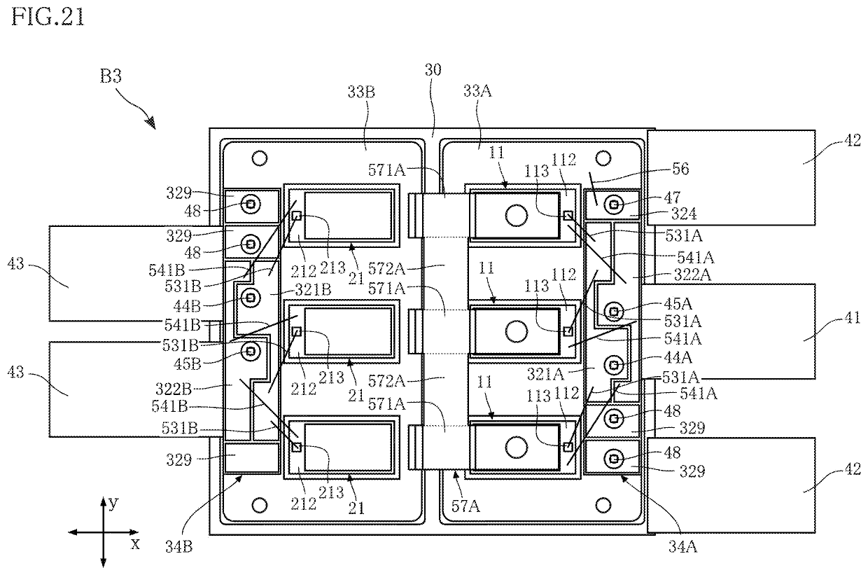

FIGS. 18-21 show a semiconductor device B3 according to a second variant of the second embodiment. The semiconductor device B3 differs from the semiconductor device B1 in the module structure. While the semiconductor device B1 is a case-type module in which the case 61 accommodates the semiconductor elements 11 and the semiconductor elements 21, the semiconductor device B3 is a mold-type module in which a sealing member 7 covers the semiconductor elements 11 and the semiconductor elements 21.

As shown in FIGS. 18-21, the semiconductor device B3 includes first semiconductor elements 11, second semiconductor elements 21, an insulating substrate 30, a pair of conductive substrates 33A, 33B, a pair of insulating layers 34A, 34B, signal wiring parts 321A, 321B, 322A, 322B, 324, 329, power terminals 41-43, signal terminals 44A, 44B, 45A, 45B, 47, 48, connection members 531A, 531B, 541A, 541B, 56, a pair of connection members 57A, 57B and a sealing member 7. As understood from the configurations discussed below, the semiconductor device A1 includes a conductive substrate 33A as an example of “a first wiring part”, and a conductive substrate 33B as an example of “a second wiring part”.

The sealing member 7 covers the semiconductor elements 11 and the semiconductor elements 21 etc. The sealing member 7 is made of black epoxy resin, for example. The sealing member 7 may be made of another insulating resin. In plan view, the sealing resin 7 may be rectangular.

The sealing member 7 includes a resin obverse face 71, a resin reverse face 72, a pair of resin side faces 73, and a pair of resin side faces 74. The resin obverse face 71 and the resin reverse face 72 are spaced apart from each other in the thickness direction z. The resin obverse face 71 faces the upside of the thickness direction z, while the resin reverse face 72 faces the downside of the thickness direction z. The paired resin side faces 73 and the paired resin side faces 74 are sandwiched between the resin obverse face 71 and the resin reverse face 72 and connected to them. In the first direction x, the paired resin side faces 73 are spaced apart and faces away from each other. In the first direction y, the paired resin side faces 74 are spaced apart and faces away from each other.

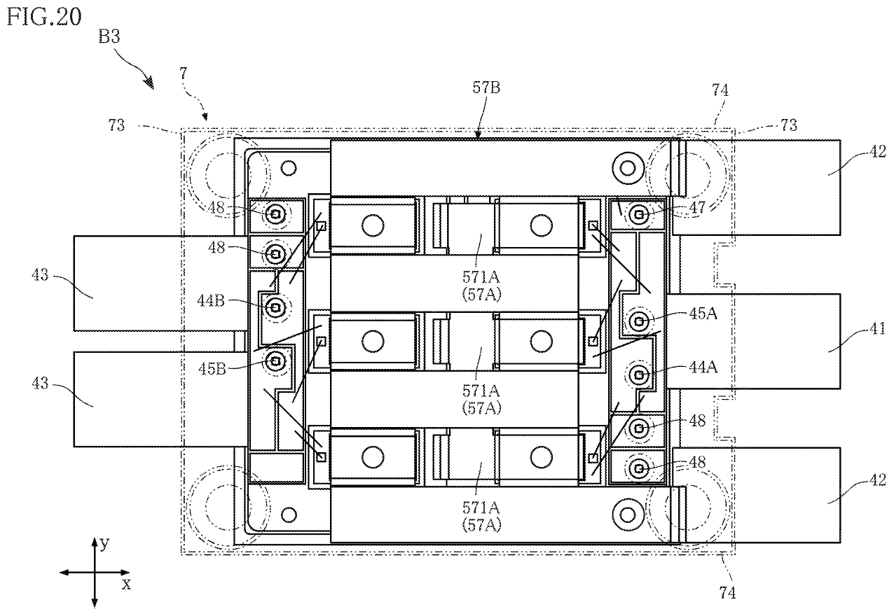

As shown in FIG. 18, the signal terminals 44A, 44B, 45A, 45B, 47, 48 protrude from the resin obverse face 71. The reverse face 30b of the insulating substrate is exposed from the resin reverse face 72. The reverse face 30b may be covered by the sealing member 7 instead of being exposed from the resin reverse face 72. As shown in FIGS. 18 and 20, the power terminal 41 and the two power terminals 42 protrude from one of the paired resin side faces 73, and the two power terminals 43 protrude from the other of the paired resin side faces 73.

Each of the conductive substrates 33A and 33B is disposed on the insulating substrate 30. The conductive substrates 33A and 33B are made of a metallic material. The metallic material includes copper, copper alloy, aluminum, or aluminum alloy.

The first semiconductor elements 11 are mounted on the conductive substrate 33A. The conductive substrate 33A faces the first element reverse faces 11b of the first semiconductor elements 11. The first electrodes 111 of the first semiconductor elements 11 are electrically connected to the conductive substrate 33A. The first electrodes 111 of the first semiconductor elements 11 are electrically connected to each other via the conductive substrate 33A.

The second semiconductor elements 21 are mounted on the conductive substrate 33B. The conductive substrate 33B faces the second element reverse faces 21b of the second semiconductor elements 21. The fourth electrodes 211 of the second semiconductor elements 21 are electrically connected to the conductive substrate 33B. The fourth electrodes 211 of the second semiconductor elements 21 are electrically connected to each other via the conductive substrate 33B.

The insulating layer 34A is disposed on the conductive substrate 33A. The signal wiring parts 321A, 322A, and 329 are disposed on the insulating layer 34A. The insulating layer 34A may be made of ceramic.

The insulating layer 34B is disposed on the conductive substrate 33B. The signal wiring parts 321B, 322B, and 329 are disposed on the insulating layer 34B. The insulating layer 34B may be made of ceramic.

The signal wiring parts 329 are each disposed on one of the insulating layers 34A and 34B. None of the connection members is joined to the signal wiring parts 329, so that the signal wiring parts 329 do not conduct to the first semiconductor elements 11 and the second semiconductor elements 21.

The power terminal 41 is formed integral with the conductive substrate 33A. In the thickness direction z, the power terminal 41 is smaller than the conductive substrate 33A. The power terminal 41 extends from the conductive substrate 33A for the one side of the first direction x. The one side of the first direction x is opposite to the conductive substrate 33B with respect to the conductive substrate 33A. The power terminal 41 conducts to the first electrodes 111 (the drain electrodes) of the first semiconductor elements 11.

The two power terminals 42 are spaced apart from the conductive substrate 33A. The two power terminals 42 are disposed opposite to each other with the power terminal 41 sandwiched therebetween in the second direction y. The two power terminals 42 are disposed offset to the one side of the first direction x with respect to the conductive substrate 33A. The power terminal 41 is located on the one side of the first direction x with respect to the conductive substrate 33A. The connection member 57B is joined to the two power terminals 42. The two power terminals 42 conduct to the fifth electrodes 212 (the source electrodes) of the second semiconductor elements 21.

The two power terminals 43 are formed integral with the conductive substrate 33B. In the thickness direction z, the two power terminals 43 are smaller than the conductive substrate 33B. Each of the two power terminals 43 extends from the conductive substrate 33B for the other side of the first direction x. The other side of the first direction x is opposite to the conductive substrate 33A with respect to the conductive substrate 33B. The two power terminals 43 conduct to the second electrodes 112 (the source electrodes) of the first semiconductor elements 11 and the fourth electrodes 211 (the drain electrodes) of the second semiconductor elements 21.

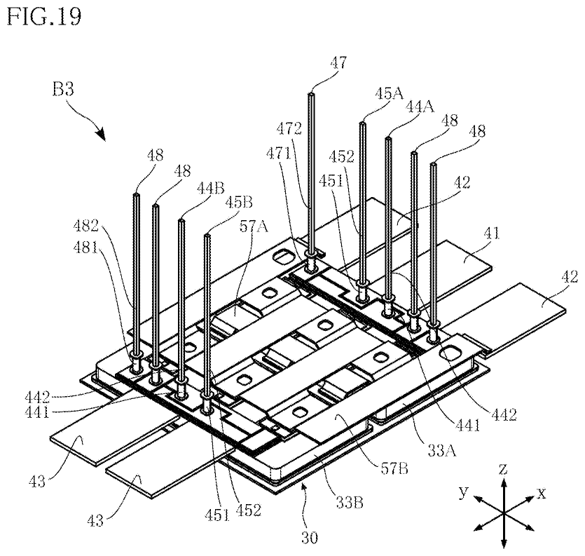

The signal terminal 44A is stood on the signal wiring part 321A. The signal terminal 44A conducts to the signal wiring part 321A. The signal terminal 44B is stood on the signal wiring part 321B. The signal terminal 44B conducts to the signal wiring part 321B. As shown in FIG. 19, the signal terminals 44A and 44B each include a holder 441 and a metal pin 442.

Each holder 441 is made of a conductive material. The holder 441 of the signal terminal 44A is joined to the signal wiring part 321A, and the holder 441 of the signal terminal 44B is joined to the signal wiring part 321B. Each holder 441 has a cylindrical shape. Each metal pin 442 is press-fitted into the holder 441 and extends in the thickness direction z. Each metal pin 442 protrudes from the resin obverse face 71 of the sealing member 7 toward the upside of the thickness direction z, thereby being partially exposed from the sealing member 7.

The signal terminal 45A is stood on the signal wiring part 322A. The signal terminal 45A conducts to the signal wiring part 322A. The signal terminal 45B is stood on the signal wiring part 322B. The signal terminal 45B conducts to the signal wiring part 322B. As shown in FIG. 19, the signal terminals 45A and 45B each include a holder 451 and a metal pin 452. The holder 451 and the metal pin 452 are configured in the same manner as the holder 441 and the metal pin 442, respectively. The holder 451 of the signal terminal 45A is joined to the signal wiring part 322A, and the holder 451 of the signal terminal 45B is joined to the signal wiring part 322B.

The signal terminal 47 is stood on the signal wiring part 324. The signal terminal 47 conducts to the signal wiring part 324. The signal wiring part 324 conducts to the conductive substrate 33A via the connection member 56. As shown in FIG. 19, the signal terminal 47 includes a holder 471 and a metal pin 472. The holder 471 and the metal pin 472 are configured in the same manner as the holder 441 and the metal pin 442, respectively. The holder 471 is joined to the signal wiring part 324.

Each of the signal terminals 48 is stood on the respective signal wiring part 329. The signal terminals 48 do not conduct to the first semiconductor elements 11 and the second semiconductor elements 21. Each of the signal terminals 48 is a non-connect terminal.

In the semiconductor device B3, with any two first semiconductor elements 11, their second electrodes 112 (the source electrodes) are electrically connected to each other via a first conduction path and a second conduction path, as with the semiconductor device B1. In the semiconductor device B3, each first conductor is formed by: the band-shaped part 571A joined to the second electrode 112 of one of the first semiconductor elements 11; the band-shaped part 571A joined to the second electrode 112 of the other of the first semiconductor elements 11; and the portion of the conductive substrate 33B interposed between the respective band-shaped part 571A. Each second conductor is formed by: the linking part 572A; and the portions of the two band-shaped parts 571A, each of which extends from the second electrode 112 to the linking part 572A. The first conduction path and the second conduction path are at least partially in parallel with each other, and the combined inductance of the first conduction path and the second conduction path is smaller than the inductance of the first conduction path. Such configuration reduces the inductance between the second electrodes 112 (the source electrodes) of any two first semiconductor elements 11 by the presence of the second conduction path. Thus, the semiconductor device B3 is advantageous in suppressing the resonance phenomenon when the first semiconductor elements 11 are operated in parallel.

In the semiconductor device B3, each of the linking parts 572A is jointed to a portion of the band-shaped part 571A located between the portion joined to the second electrode 112 and the portion of the band-shaped part 571A joined to the conductive substrate 33B. Such configuration can shorten the length of the second conduction path than the length of the first conduction path in electrically connecting the second electrodes 112 of the two first semiconductor elements 11, which results in the reduction of the inductance of the second conduction path than the inductance of the first conduction path.

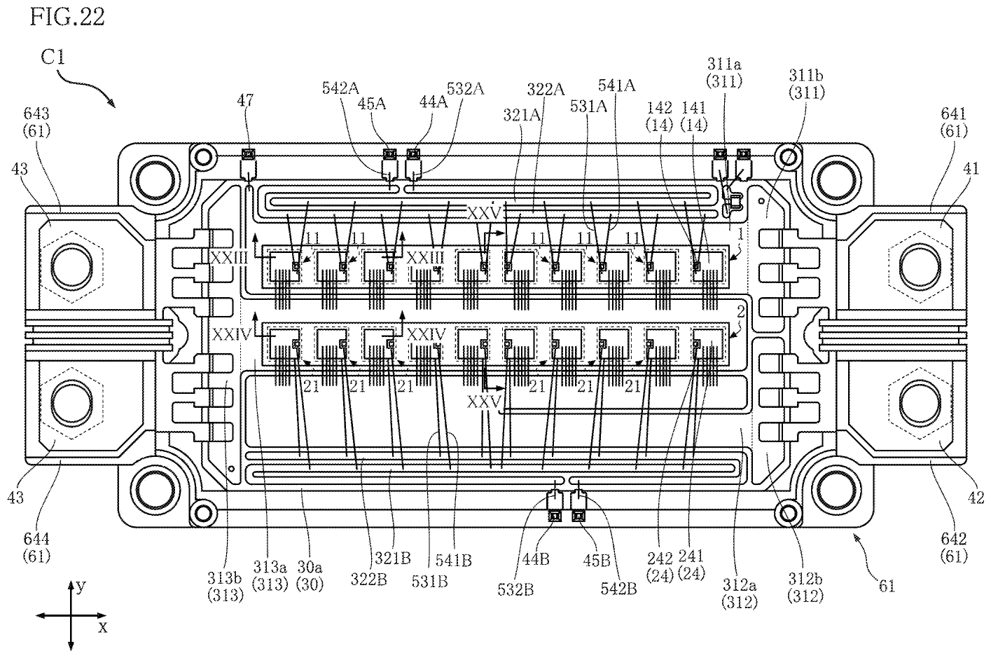

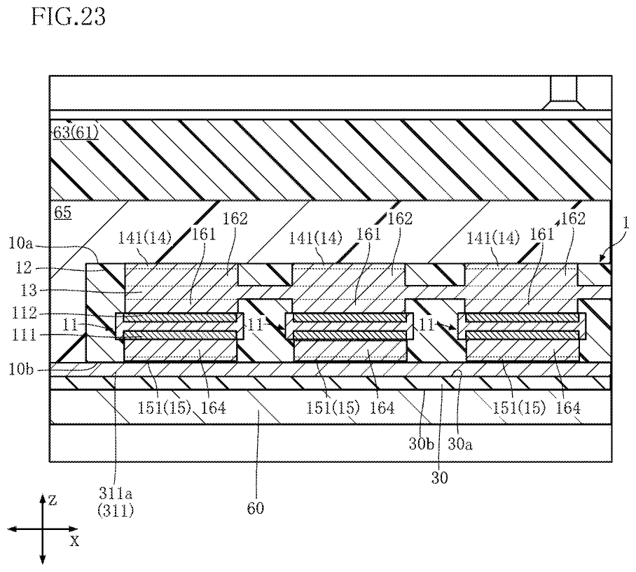

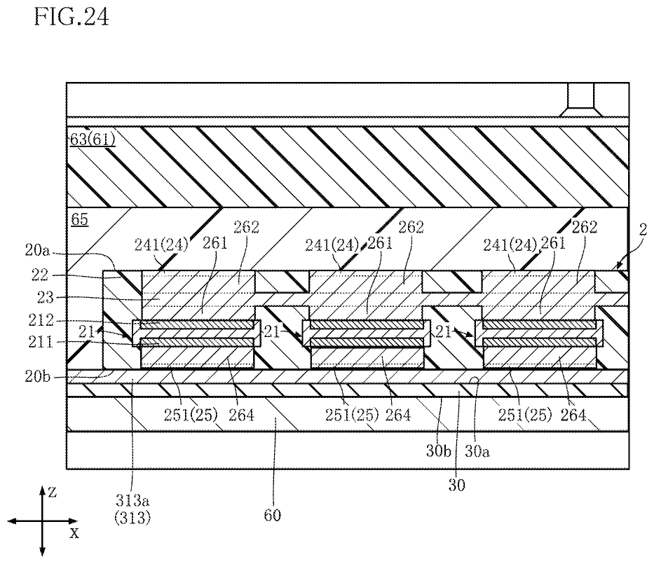

FIGS. 22-25 show a semiconductor device C1 according to a third embodiment. The semiconductor device C1 differs from the semiconductor device A1 in the following. First, the first semiconductor elements 11 are covered by a resin member 12 and provide a first switching part 1. Second, the second semiconductor elements 21 are covered by a resin member 22 and provide a second switching part 2.

The first switching part 1 is a single component in which the first semiconductor elements 11 are integrated by using a rewiring technology. The first switching part 1 has an obverse face 10a and a reverse face 10b. The obverse face 10a and the reverse face 10b are spaced apart from each other in the thickness direction z. The obverse face 10a faces the one side (upside) of the thickness direction z. The reverse face 10b faces the other side (downside) of the thickness direction z and hence the pad part 311a (power wiring part 311). The first switching part 1 includes first semiconductor elements 11, a resin member 12, a wiring layer 13, obverse terminal parts 14, reverse terminal parts 15, and interlayer electrodes 161-164. As understood from the following description, the semiconductor device C1 includes the resin member 12, the wiring layer 13, and the obverse terminal parts 14.

The resin member 12 covers the first semiconductor elements 11, the wiring layer 13, and the interlayer electrodes 161-164. The resin member 12 may be made of an insulating resin member.

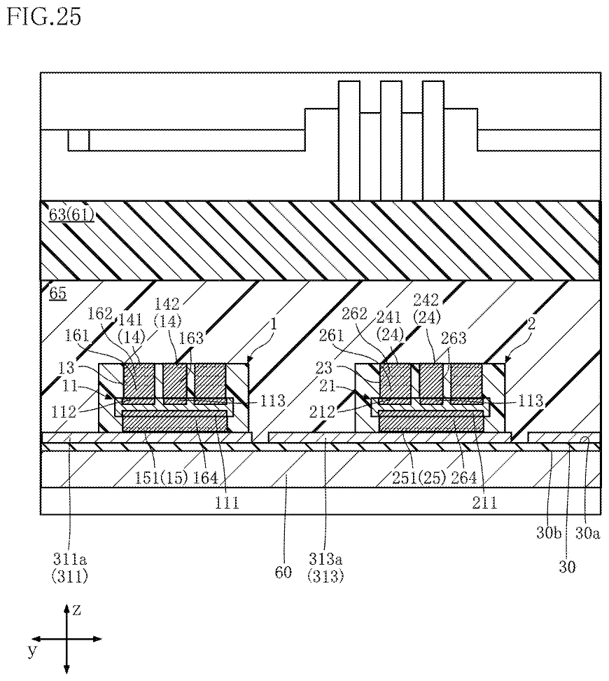

In plan view, the wiring layer 13 has a band shape extending along an arrangement direction of the first semiconductor elements 11 (the first direction x). In plan view, the wiring layer 13 overlaps with the first semiconductor elements 11. However, as understood from FIG. 25, the wiring layer 13 is formed not to overlap with the third electrodes 113.

The obverse terminal parts 14 are disposed on the obverse face 10a and exposed from the resin member 12. The obverse terminal parts 14 include first pad parts 141 and second pad parts 142. Each first pad part 141 conducts to the second electrode 112 (the source electrode) of each first semiconductor element 11 via the wiring layer 13 and the two interlayer electrodes 161 and 162. The number of the first pad parts 141 may be equal to the number of the first semiconductor elements 11 (second electrodes 112). Each second pad part 142 conducts to the third electrode 113 (the gate electrode) of each first semiconductor element 11 via the interlayer electrode 163. The number of the second pad parts 142 may be equal to the number of the first semiconductor elements 11 (third electrodes 113).

The reverse terminal parts 15 are disposed on the reverse face 10b and exposed from the resin member 12. The reverse terminal parts 15 include pad parts 151. Each pad part 151 conducts to the first electrode 111 (the drain electrode) of a relevant first semiconductor element 11 via the interlayer electrode 164.

The interlayer electrodes 161-164 extend in the thickness direction z. Each interlayer electrode 161 is connected between the second electrode 112 of a relevant first semiconductor element 11 and the wiring layer 13. Each interlayer electrode 162 is connected between the wiring layer 13 and a relevant first pad part 141. Each interlayer electrode 163 is connected between the third electrode 113 of a relevant first semiconductor element 11 and a relevant second pad part 142. Each interlayer electrode 164 is connected between the first electrode 111 of a relevant first semiconductor element 11 and a relevant pad part 151.

The second switching part 2 is a single component in which the second semiconductor elements 21 are integrated by using a rewiring technology, as with the first switching part 1. The second switching part 2 has an obverse face 20a and a reverse face 20b. The obverse face 20a and the reverse face 20b are spaced apart from each other in the thickness direction z. The obverse face 20a faces the one side (upside) of the thickness direction z. The reverse face 20b faces the other side (downside) of the thickness direction z and hence the pad part 313a (power wiring part 313). The second switching part 2 includes second semiconductor elements 21, a resin member 22, a wiring layer 23, obverse terminal parts 24, reverse terminal parts 25, and interlayer electrodes 261-264.

The resin member 22 covers the second semiconductor elements 21, the wiring layer 23, and the interlayer electrodes 261-264. The resin member 22 may be made of an insulating resin member.

In plan view, the wiring layer 23 has a band shape extending along an arrangement direction of the second semiconductor elements 21 (the first direction x). In plan view, the wiring layer 23 overlaps with the second semiconductor elements 21. However, as understood from FIG. 25, the wiring layer 23 is formed not to overlap with the sixth electrodes 213.

The obverse terminal parts 24 are disposed on the obverse face 10a and exposed from the resin member 22. The obverse terminal parts 24 include first pad parts 241 and second pad parts 242. Each first pad part 241 conducts to the fifth electrode 212 (the source electrode) of each second semiconductor element 21 via the wiring layer 23 and the two interlayer electrodes 261 and 262. The number of the first pad parts 241 may be equal to the number of the second semiconductor elements 21 (fifth electrodes 212). Each second pad part 242 conducts to the sixth electrode 213 (the gate electrode) of each second semiconductor element 21 via the interlayer electrode 263. The number of the second pad parts 242 may be equal to the number of the second semiconductor elements 21 (sixth electrodes 213).

The reverse terminal parts 25 are disposed on the reverse face 20b and exposed from the resin member 22. The reverse terminal parts 25 include pad parts 251. Each pad part 251 conducts to the fourth electrode 211 (the drain electrode) of each second semiconductor element 21 via the interlayer electrode 264.

The interlayer electrodes 261-264 extend in the thickness direction z. Each interlayer electrode 261 is connected between the fifth electrode 212 of a relevant second semiconductor element 21 and the wiring layer 23. Each interlayer electrode 262 is connected between the wiring layer 23 and a relevant first pad part 241. Each interlayer electrode 263 is connected between the sixth electrode 213 of a relevant second semiconductor element 21 and a relevant second pad part 242. Each interlayer electrode 264 is connected between the fourth electrode 211 of a relevant second semiconductor element 21 and a relevant pad part 251.

Effects of the semiconductor device C1 are as follows.

The semiconductor device C1 includes first conductors and second conductors, as with the semiconductor devices A1 and B1. In the semiconductor device C1, each first conductor is formed by: the portion extending from the second electrode 112 of one of the first semiconductor elements 11 to the relevant first pad part 141 on the second electrode 112 (the two interlayer electrodes 161 and 162 and a part of the wiring layer 13); the connection member 51A joined to the first pad part 141; the portion extending from the second electrode 112 of the other of the first semiconductor elements 11 to the first pad part 141 on the second electrode 112 (the two interlayer electrodes 161 and 162 and a part of the wiring layer 13); the connection member 51A joined to the first pad part 141; and the portion of the pad part 313a (power wiring part 313) between the joint locations of the connection members 51A. Each second conductor is formed by: the interlayer electrode 161 in contact with the second electrode 112 of one of the first semiconductor elements 11; the interlayer electrode 161 in contact with the second electrode 112 of the other of the first semiconductor elements 11; and the portion of the wiring layer 13 between the portions in contact with the interlayer electrodes 161. With any two first semiconductor elements 11, their second electrodes 112 (the source electrodes) are electrically connected to each other via a first conduction path provided by the first conductor and a second conduction path provided by the second conductor. In the semiconductor device C1, the first conduction path is a path between the second electrodes 112 that conducts when the main current path is formed, as with the semiconductor devices A1 and B1. The first conduction path and the second conduction path are at least partially in parallel with each other, and the combined inductance of the first conduction path and the second conduction path is smaller than the inductance of the first conduction path. Such configuration reduces the inductance between the second electrodes 112 (the source electrodes) of any two first semiconductor elements 11 by the presence of the second conduction path. Thus, the semiconductor device C1 is advantageous in suppressing the resonance phenomenon when the first semiconductor elements 11 are operated in parallel.

In the semiconductor device C1, the first switching part 1 includes the wiring layer 13. Within the resin member 12, the wiring layer 13 electrically connects the second electrodes 112 of the first semiconductor elements 11 to each other. Such configuration can shorten the length of the second conduction path than the length of the first conduction path in electrically connecting the second electrodes 112 of the two first semiconductor elements 11. Further, in the semiconductor device C1, the second conduction path is shorter than the first conduction path, so that the inductance of the second conduction path can be reduced than the inductance of the first conduction path.

The semiconductor device C1 includes third conductors and fourth conductors, as with the semiconductor devices A1 and B1. In the semiconductor device C1, each third conductor is formed by: the portion extending from the fifth electrode 212 of one of the second semiconductor elements 21 to the relevant first pad part 241 (the two interlayer electrodes 261 and 262 and a part of the wiring layer 23); the connection member 51B joined to the first pad part 241; the portion extending from the fifth electrode 212 of the other of the second semiconductor elements 21 to the first pad part 241 on the fifth electrode 212 (the two interlayer electrodes 261 and 262 and a part of the wiring layer 23); the other connection member 51B joined to the first pad part 241; and the portion of the pad part 313a (power wiring part 313) between the joint locations of the connection members 51A. Each fourth conductor is formed by: the interlayer electrode 261 in contact with the fifth electrode 212 of one of the second semiconductor elements 21; the interlayer electrode 261 in contact with the fifth electrode 212 of the other of the second semiconductor elements 21; and the portion of the wiring layer 13 interposed between the portions in contact with the interlayer electrodes 261. With any two second semiconductor elements 21, their fifth electrodes 212 (the source electrodes) are electrically connected to each other via a third conduction path provided by the third conductor and a fourth conduction path provided by the fourth conductor. In the semiconductor device C1, the third conduction path is a path between the fifth electrodes 212 that conducts when the main current path is formed, as with the semiconductor devices A1 and B1. The third conduction path and the fourth conduction path are at least partially in parallel with each other, and the combined inductance of the third conduction path and the fourth conduction path is smaller than the inductance of the third conduction path. Such configuration reduces the inductance between the fifth electrodes 212 (the source electrodes) of any two second semiconductor elements 21 by the presence of the fourth conduction path. Thus, the semiconductor device C1 is advantageous in suppressing the resonance phenomenon when the second semiconductor elements 21 are operated in parallel.

In the semiconductor device C1, the second switching part 2 includes the wiring layer 23. Within the resin member 22, the wiring layer 23 electrically connects the fifth electrodes 212 of the second semiconductor elements 21 to each other. Such configuration can shorten the length of the fourth conduction path than the length of the third conduction path in electrically connecting the fifth electrodes 212 of the two second semiconductor elements 21. Further, in the semiconductor device C1, the fourth conduction path is shorter than the third conduction path, so that the inductance of the fourth conduction path can be reduced than the inductance of the third conduction path.

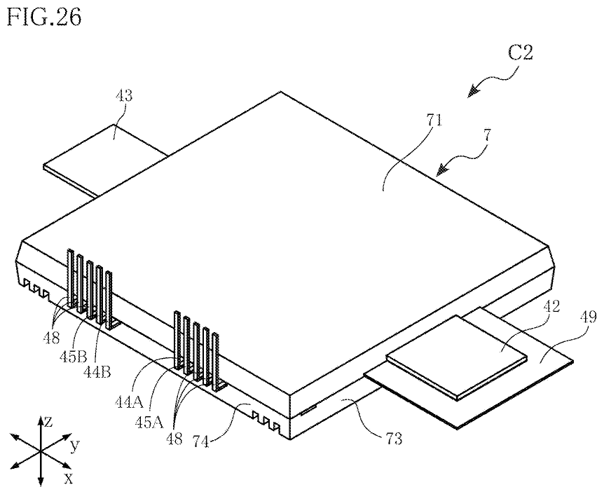

FIGS. 26-28 show a semiconductor device C2 according to a variant of the third embodiment. The semiconductor device C2 differs from the semiconductor device C1 in the module structure.

As shown FIGS. 26-28, the semiconductor device C2 includes a first switching part 1, a second switching part 2, an insulating substrate 30, a pair of conductive substrates 33A and 33B, a pair of insulating layers 34A and 34B, signal wiring parts 321A, 321B, 322A and 322B, power terminals 41-43, signal terminals 44A, 44B, 45A, 45B and 48, connection members 531A, 531B, 532A, 532B, 541A, 541B, 542A and 542B, and a sealing member 7. As understood from the configurations discussed below, the semiconductor device C2 includes a conductive substrate 33A as an example of “a first wiring part”, and a conductive substrate 33B as an example of “a second wiring part”.

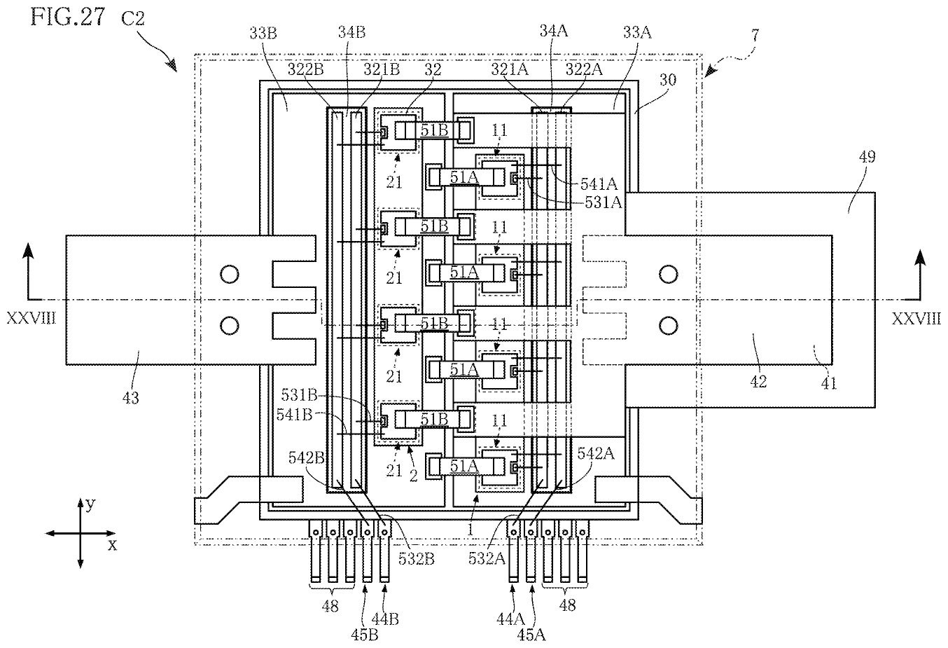

In the semiconductor device C2, the first switching part 1 is, as shown in FIG. 27, mounted on the conductive substrate 33A. The reverse face 10b faces the conductive substrate 33A. The reverse terminal part 15 (pad parts 151) of the first switching part 1 is joined to the conductive substrate 33A, thereby electrically conducting to the first electrodes 111 of the first semiconductor elements 11. The first electrodes 111 of the first semiconductor elements 11 are electrically connected to each other via the conductive substrate 33A.

In the semiconductor device C2, the second switching part 2 is, as shown in FIG. 27, mounted on the conductive substrate 33B. The reverse face 20b faces the conductive substrate 33B. The reverse terminal part 25 (pad parts 251) of the second switching part 2 is joined to the conductive substrate 33B, thereby electrically conducting to the fourth electrodes 211 of the second semiconductor elements 21. The fourth electrodes 211 of the second semiconductor elements 21 are electrically connected to each other via the conductive substrate 33B.

In the semiconductor device C2, each of the connection members 51A and 51B is, as shown in FIG. 27, a metal plate member. Each of the connection members 51A is, as shown in FIG. 27, joined to the respective first pad part 141 and the conductive substrate 33B. Each of the connection members 51B is, as shown in FIG. 27, joined to the respective first pad part 241 and a part of the power terminal 42 (each of the portions formed in a comb-like shape).

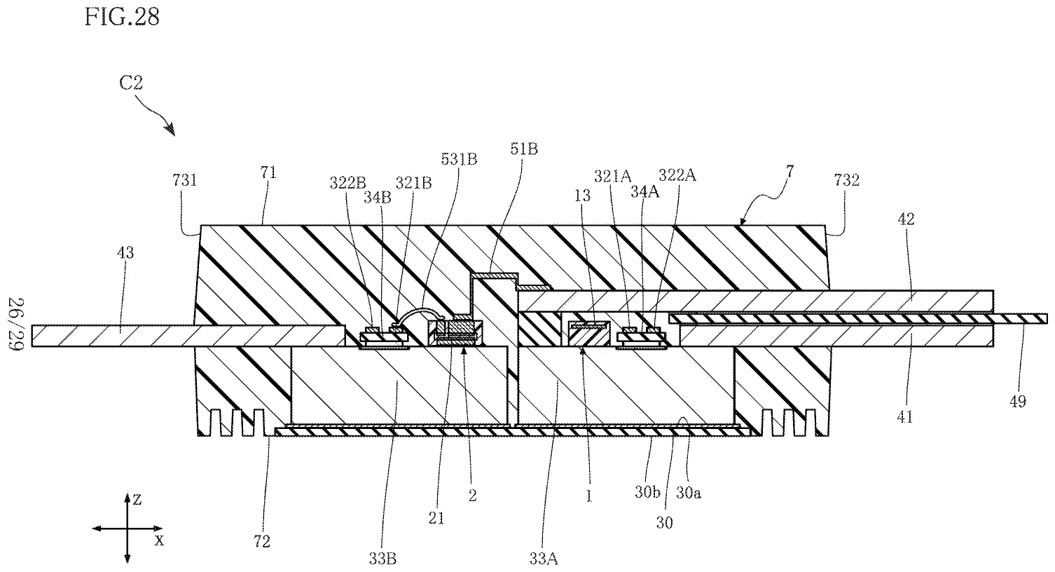

The power terminal 41 is joined to the conductive substrate 33A, thereby electrically conducting to the first electrodes 111 of the first semiconductor elements 11. As shown in FIG. 28, the power terminal 42 is stacked on the power terminal 41 with the insulating substrate 49 sandwiched therebetween. The power terminal 42 electrically conducts to the fifth electrodes 212 of the second semiconductor elements 21 via the connection members 51B. The power terminal 43 is joined to the conductive substrate 33B, thereby electrically conducting to the fourth electrodes 211 of the second semiconductor elements 21. The power terminal 43 are also electrically connected to the second electrodes 112 of the first semiconductor elements 11 via the conductive substrate 33B and the connection members 51A.

In the semiconductor device C2, with any two first semiconductor elements 11, their second electrodes 112 (the source electrodes) are electrically connected to each other via a first conduction path and a second conduction path, as with the semiconductor device C1. In the semiconductor device C2, each first conductor includes a part of the conductive substrate 33B instead of a part of the pad part 313a. The first conduction path and the second conduction path are at least partially in parallel with each other, and the combined inductance of the first conduction path and the second conduction path is smaller than the inductance of the first conduction path. As with the semiconductor device C1, such configuration reduces the inductance between the second electrodes 112 (the source electrodes) of any two first semiconductor elements 11 by the presence of the second conduction path. Thus, the semiconductor device C2 is advantageous in suppressing the resonance phenomenon when the first semiconductor elements 11 are operated in parallel.

In the semiconductor device C2, with any two first semiconductor elements 21, their fifth electrodes 212 (the source electrodes) are electrically connected to each other via a third conduction path and a fourth conduction path, as with the semiconductor device C1. In the semiconductor device C2, each third conductor includes a part of the power terminal 42 instead of a part of the pad part 312a. The third conduction path and the fourth conduction path are at least partially in parallel with each other, and the combined inductance of the third conduction path and the fourth conduction path is smaller than the inductance of the third conduction path. As with the semiconductor device C1, such configuration reduces the inductance between the fifth electrodes 212 (the source electrodes) of any two second semiconductor elements 21 by the presence of the fourth conduction path. Thus, the semiconductor device C2 is advantageous in suppressing the resonance phenomenon when the second semiconductor elements 21 are operated in parallel.

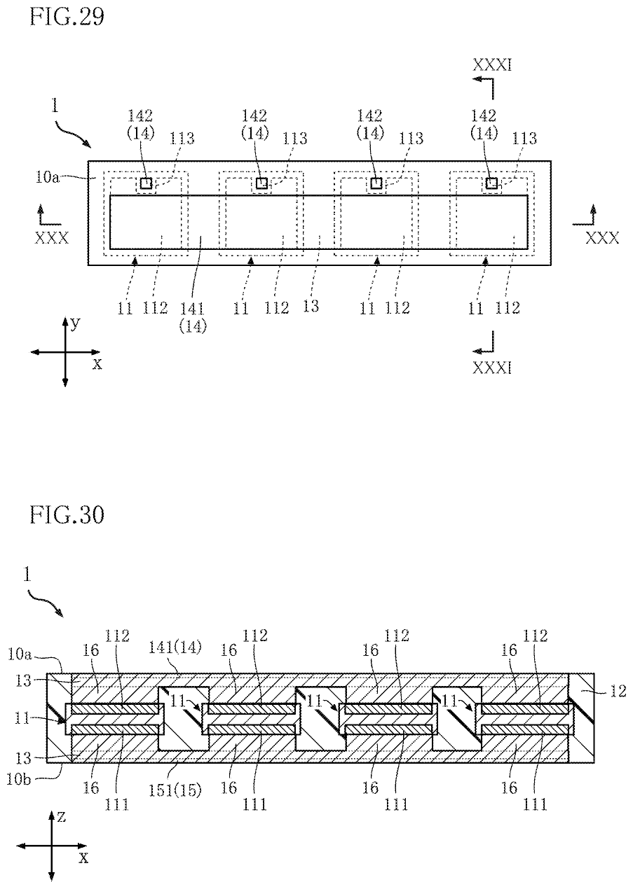

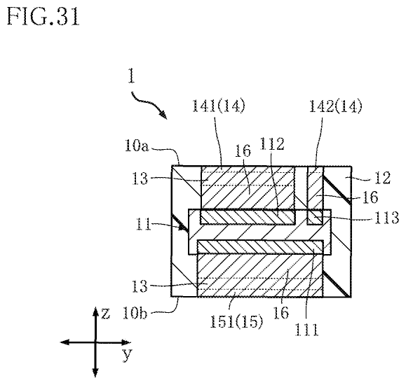

In each of the semiconductor devices C1 and C2, the first switching part 1 may have the configuration shown in FIGS. 29-31. An example shown in FIGS. 29-31 has the switching part 1 with four first semiconductor elements 11. In the example of FIGS. 29-31, the obverse terminal part 14 of the first switching part 1 includes the single first pad part 141 instead of the plurality of first pad parts 141. As shown in FIG. 30, the first pad part 141 is formed on the surface (the upper face in the thickness direction z) of the relevant wiring layer 13 that is electrically connected to the second electrodes 112 of the first semiconductor elements 11. In the example of FIGS. 29-31, the reverse terminal part 15 of the first switching part 1 includes the single pad part 151 instead of the plurality of pad parts 151. As shown in FIG. 30, the pad part 151 is formed on the surface (the lower face in the thickness direction z) of the relevant wiring layer 13 that is electrically connected to the first electrodes 111 of the first semiconductor elements 11. As with the semiconductor devices C1 and C2, the reverse terminal part 15 may be configured to include the plurality of pad parts 151 instead of the single pad part 151. In such configuration of the first switching part 1, the second electrodes 112 are electrically connected to each other via the relevant wiring layer 13, thereby forming the conduction path through the second conductor. Such configuration may be applied to the second switching part 2 in addition to the first switching part 1.

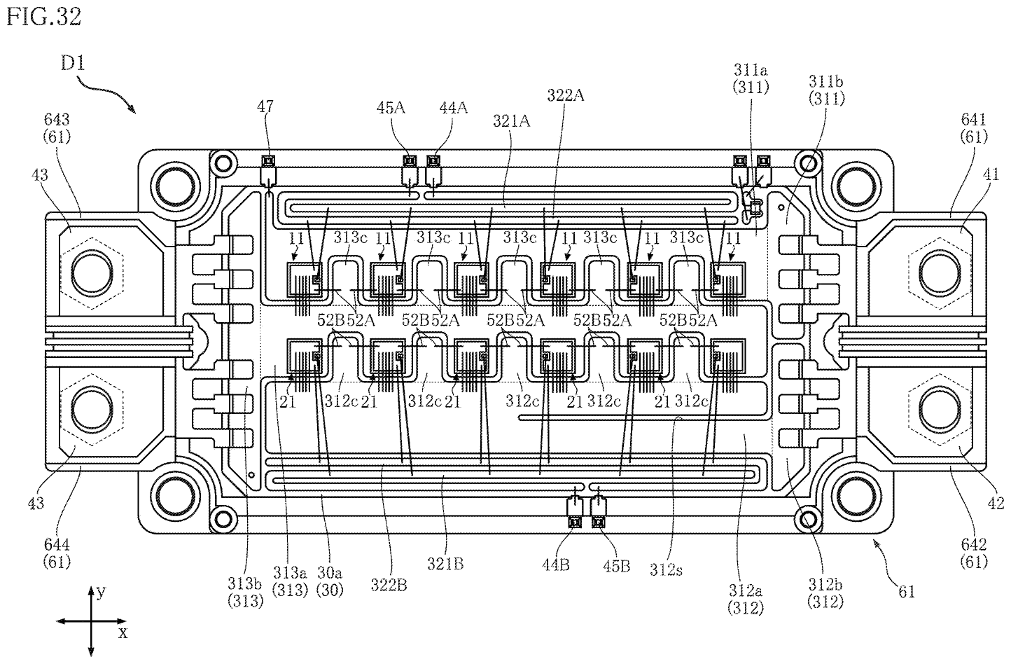

FIG. 32 shows a semiconductor device D1 according to a fourth embodiment. As shown in FIG. 32, the semiconductor device D1 differs from the semiconductor device A1 in shapes of the power wiring parts 311-313 in plan view.

The power wiring part 312 of the semiconductor device D1 further includes protruding parts 312c, which differs from the power wiring part 312 of the semiconductor device A1. The power wiring part 313 of the semiconductor device D1 further includes protruding parts 313c, which differs from the power wiring part 313 of the semiconductor device A1.

Each of the protruding parts 312c projects from the pad part 312a toward one side of the second direction y (the side on which the second semiconductor elements 21 are located). In plan view, each protruding part 312c is disposed between the two relevant second semiconductor elements 21 adjacent in the first direction x. Two connection members 52B are joined to each of the protruding part 312c. In plan view, the connection members 52B are joined to the fifth electrodes 212 of the two relevant second semiconductor elements 21 adjacent in the first direction x.

Each of the protruding parts 313c projects from the pad part 313a toward one side of the second direction y (the side on which the first semiconductor elements 11 are located). In plan view, each protruding part 313c is disposed between the two relevant first semiconductor elements 11 adjacent in the first direction x. Two connection members 52A are joined to each of the protruding parts 313c. In plan view, the connection members 52A are joined to the second electrodes 112 of the two relevant first semiconductor elements 11 adjacent in the first direction x.

Effects of the semiconductor device D1 are as follows.

The semiconductor device D1 includes first conductors and second conductors, as with the semiconductor devices A1, B1 and C1. In the semiconductor device D1, each first conductor is, as with the semiconductor devices A1, formed by: the connection members 51A joined to the second electrode 112 of one of the first semiconductor elements 11; the connection members 51A joined to the second electrode 112 of the other of the first semiconductor elements 11; and the portion of the pad part 313a (power wiring part 313) between the connected portions of the respective connection members 51A. Each second conductor is formed by: the protruding part 313c, which is disposed between the two first semiconductor elements 11; and the two connection members 52A joined to the relevant protruding part 313c. With any two first semiconductor elements 11 adjacent in the first direction x, their second electrodes 112 are electrically connected to each other via a first conduction path provided by the first conductor and a second conduction path provided by the second conductor. In the semiconductor device D1, the first conduction path is a path between the second electrodes 112 that conducts when the main current path is formed, as with the semiconductor devices A1, B1 and C1. The first conduction path and the second conduction path are at least partially in parallel with each other, and the combined inductance of the first conduction path and the second conduction path is smaller than the inductance of the first conduction path. Such configuration reduces the inductance between the second electrodes 112 (the source electrodes) of any two first semiconductor elements 11 adjacent in the first direction x by the presence of the second conduction path. Thus, the semiconductor device D1 is advantageous in suppressing the resonance phenomenon when the first semiconductor elements 11 are operated in parallel.

In the semiconductor device D1, the power wiring part 313 includes the protruding parts 313c, which project from the pad part 313a and are each disposed between the respective two first semiconductor elements 11 adjacent in the first direction x. Each connection member 52A, which is joined to the second electrodes 112 of the respective two first semiconductor elements 11, is joined to the protruding part 313c. Such configuration can shorten the length of the second conduction path than the length of the first conduction path in electrically connecting the second electrodes 112 of the two first semiconductor elements 11 adjacent in the first direction x. Further, in the semiconductor device D1, the second conduction path is shorter than the first conduction path, so that the inductance of the second conduction path can be reduced than the inductance of the first conduction path.

In the semiconductor device D1, each protruding part 313c is disposed between the relevant two first semiconductor elements 11 adjacent in the first direction x. In the semiconductor device A1, for example, the first electrodes 111 of any two first semiconductor elements 11 adjacent in the first direction x are electrically connected to each other via the conduction path connecting straight the first electrodes 111 on the pad part 311a. However, in the semiconductor device D1, the first electrodes 111 of any two first semiconductor elements 11 adjacent in the first direction x are electrically connected to each other via the path avoiding the relevant protruding part 313c on the pad part 311a. Namely, the semiconductor device D1 has a longer conduction path than the semiconductor device A1 since each protruding part 313c is disposed in the manner that interrupts the conduction path connecting straight the relevant two first electrodes 111 adjacent in the first direction x. Hence, compared to the semiconductor device A1, the semiconductor device D1 has the greater inductance between any two first electrodes 111. Through the study by the inventors, it has been found that the conduction path between the first electrodes 111 of any two first semiconductor elements 11 with a greater inductance can prevent the occurrence of resonance phenomenon. Thus, the semiconductor device D1 is more advantageous than the semiconductor device A1 in suppressing the resonance phenomenon when the first semiconductor elements 11 are operated in parallel.

The semiconductor device D1 includes third conductors and fourth conductors, as with the semiconductor devices A1, B1 and C1. In the semiconductor device D1, each third conductor is, as with the semiconductor devices A1, formed by: the connection members 51B joined to the fifth electrode 212 of one of the second semiconductor elements 21; the connection members 51B joined to the fifth electrode 212 of the other of the second semiconductor elements 21; and the portion of the pad part 312a (power wiring part 312) between the connected portions of the connection members 51B. Each second conductor is formed by: the protruding part 312c, which is disposed between the two second semiconductor elements 21; and the two connection members 52B joined to the relevant protruding part 312c. With any two second semiconductor elements 21 adjacent in the first direction x, their fifth electrodes 212 are electrically connected to each other via a third conduction path provided by the third conductor and a fourth conduction path provided by the fourth conductor. In the semiconductor device D1, the third conduction path is a path between the fifth electrodes 212 that conducts when the main current path is formed, as with the semiconductor devices A1, B1 and C1. The third conduction path and the fourth conduction path are at least partially in parallel with each other, and the combined inductance of the third conduction path and the fourth conduction path is smaller than the inductance of the third conduction path. Such configuration reduces the inductance between the fifth electrodes 212 (the source electrodes) of any two second semiconductor elements 21 adjacent in the first direction x by the presence of the fourth conduction path. Thus, the semiconductor device D1 is advantageous in suppressing the resonance phenomenon when the second semiconductor elements 21 are operated in parallel.

In the semiconductor device D1, the power wiring part 312 includes the protruding parts 312c, which project from the pad part 312a and are each disposed between the respective two second semiconductor elements 21 adjacent in the first direction x. Each connection member 52B, which is joined to the second electrodes 112 of the respective two first semiconductor elements 11, is joined to the protruding part 312c. Such configuration can shorten the length of the fourth conduction path than the length of the third conduction path in any two second semiconductor elements 21 adjacent in the first direction x. Further, in the semiconductor device D1, the fourth conduction path is shorter than the third conduction path, so that the inductance of the fourth conduction path can be reduced than the inductance of the third conduction path.

In the semiconductor device D1, each protruding part 312c is disposed between the relevant two second semiconductor elements 21 adjacent in the first direction x. In the semiconductor device A1, for example, the fourth electrodes 211 of any two second semiconductor elements 21 adjacent in the first direction x are electrically connected to each other via the conduction path connecting straight the fourth electrodes 211 on the pad part 313a. However, in the semiconductor device D1, the fourth electrodes 211 of any two second semiconductor elements 21 adjacent in the first direction x are electrically connected to each other via the path avoiding the relevant protruding part 312c on the pad part 313a. Namely, the semiconductor device D1 has a longer conduction path than the semiconductor device A1 since each protruding part 312c is disposed in the manner that interrupts the conduction path connecting straight the relevant two fourth electrodes 211 adjacent in the first direction x. Hence, compared to the semiconductor device A1, the semiconductor device D1 has the greater inductance between any two fourth electrodes 211. Thus, the semiconductor device D1 is more advantageous than the semiconductor device A1 in suppressing the resonance phenomenon when the second semiconductor elements 21 are operated in parallel.

The semiconductor devices according to the present disclosure are not limited to the embodiments described above. The specific configuration of each part of a semiconductor device according to the present disclosure may suitably be designed and changed in various manners. The present disclosure includes the embodiments described in the following clauses.

Clause 1. A semiconductor device comprising:
two first semiconductor elements each having a first electrode, a second electrode, and a third electrode, with a switching operation being controlled depending on a first driving signal inputted to the third electrode;
a first conductor electrically connecting the second electrodes of the two first semiconductor elements;
a second conductor electrically connecting the second electrodes of the two first semiconductor elements; and
a first power terminal electrically connected to the first conductor and electrically conducting to the second electrodes of the two first semiconductor elements,
wherein the two first semiconductor elements are connected in parallel with each other,
a first conduction path and a second conduction path are provided by the first conductor and the second conductor, respectively, between the second electrodes of the two first semiconductor elements,
the first conduction path and the second conduction path are at least partially in parallel, and
a combined inductance of the first conduction path and the second conduction path is smaller than an inductance of the first conduction path.

Clause 2. The semiconductor device according to clause 1, wherein an inductance of the second conduction path is smaller than the inductance of the first conduction path.

Clause 3. The semiconductor device according to clause 1 or 2, wherein a length of the second conduction path is shorter than a length of the first conduction path

Clause 4. The semiconductor device according to any of clauses 1 to 3, further comprising:
a first wiring part and a second wiring part spaced apart from each other; and
a first connection member electrically connected to the second electrodes of the two first semiconductor elements,
wherein the first wiring part is electrically connected to the first electrodes of the two first semiconductor elements,
the second wiring part is joined by the first connection member, thereby electrically connected to the second electrodes of the two first semiconductor elements via the first connection member, and
the first conductor includes a part of the first connection member and a part of the second wiring part.

Clause 5. The semiconductor device according to clause 4, wherein each of the two first semiconductor elements has a first element obverse face and a first element reverse face spaced apart from each other in a thickness direction of the first semiconductor elements, and
in each of the two first semiconductor elements, the first electrode is disposed on the first element reverse face, and the second electrode and the third electrode are disposed on the first element obverse face.

Clause 6. The semiconductor device according to clause 5, wherein each of the two first semiconductor elements is mounted on the first wiring part with the first element reverse face facing the first wiring part.

Clause 7. The semiconductor device according to clause 6, wherein the second conductor includes a second connection member, and
the second connection member is joined to the second electrodes of the two first semiconductor elements.

Clause 8. The semiconductor device according to clause 7, wherein the second connection member is a bonding wire.

Clause 9. The semiconductor device according to clause 6, wherein the first connection member includes two band-shaped parts spaced apart from each other, and a linking part connected to and disposed between the two band-shaped parts,
one of the two band-shaped parts is joined to the second electrode of one of the two first semiconductor elements and to the second wiring part;
the other of the two band-shaped parts is joined to the second electrode of the other of the two first semiconductor elements and to the second wiring part,
the first conductor includes the two band-shaped parts and a portion of the second wiring part interposed between joints of the two band-shaped parts, and
the second conductor includes the linking part and portions of the two band-shaped parts, each of which extends from a joint of the second electrode to the linking part.

Clause 10. The semiconductor device according to clause 9, wherein the linking part is connected to portions of the two band-shaped parts, which overlap with the respective two first semiconductor elements as viewed in the thickness direction.

Clause 11. The semiconductor device according to clause 6 further comprising:
a resin member overlapping with at least a part of each of the two first semiconductor elements;
a wiring layer disposed above the first element obverse faces of the two first semiconductor elements and covered by the resin member; and
a terminal part exposed from the resin member and joined by the first connection member,
wherein the terminal part is electrically connected to the second electrodes of the two first semiconductor elements; and
the wiring layer is electrically connected to the second electrodes of the two first semiconductor elements and overlaps with the second electrodes of the two first semiconductor elements as viewed in the thickness direction.

Clause 12. The semiconductor device according to clause 11, wherein the terminal part includes two pad parts spaced apart from each other and joined by the first connection member;
one of the two pad parts overlaps with the second electrode of one of the two first semiconductor elements as viewed in the thickness direction; and
the other of the two pad parts overlaps with the second electrode of the other of the two first semiconductor elements as viewed in the thickness direction.

Clause 13. The semiconductor device according to any of clauses 6 to 12 further comprising:
two second semiconductor elements each having a fourth electrode, a fifth electrode, and a sixth electrode, with a switching operation being controlled depending on a second driving signal inputted to the sixth electrode;
a third conductor electrically connecting the fifth electrodes of the two second semiconductor elements;
a fourth conductor electrically connecting the fifth electrodes of the two second semiconductor elements; and
a second power terminal electrically connected to the third conductor and the fifth electrodes of the two second semiconductor elements,
wherein the two second semiconductor elements are connected in parallel with each other;
a third conduction path and a fourth conduction path are provided between the fifth electrodes of the two second semiconductor elements and extend through the third conductor and the fourth conductor, respectively,
the third conduction path and the fourth conduction path are at least partially in parallel, and
a combined inductance of the third conduction path and the fourth conduction path is smaller than an inductance of the third conduction path.

Clause 14. The semiconductor device according to clause 13, wherein an inductance of the fourth conduction path is smaller than the inductance of the third conduction path.

Clause 15. The semiconductor device according to clause 13 or 14, wherein a length of the fourth conduction path is shorter than a length of the third conduction path.

Clause 16. The semiconductor device according to any of clauses 13 to 15 further comprising:
a third wiring part spaced apart from the first wiring part and the second wiring part; and
a third connection member electrically connected to the fifth electrodes of the two second semiconductor elements,
wherein the second wiring part is electrically connected to the fourth electrodes of the two second semiconductor elements;
the third wiring part is joined by the third connection member, thereby electrically conducting to the fifth electrodes of the two second semiconductor elements via the third connection member; and
the third conductor includes a part of the third connection member and a part of the third wiring part.

Clause 17. The semiconductor device according to clause 16 further comprising a third power terminal connected to the first wiring part,
wherein the second power terminal and the third power terminal are input terminals for a direct voltage;
the direct voltage is converted into an alternating voltage by switching operations of the two first semiconductor elements and the two second semiconductor elements; and
the first power terminal is an output terminal for the alternating voltage.

Clause 18. The semiconductor device according to any of clauses 13 to 17, wherein each of the two second semiconductor elements is a MOSFET;
the fourth electrode is a drain electrode;
the fifth electrode is a source electrode; and
the sixth electrode is a gate electrode.

Clause 19. The semiconductor device according to any of clauses 1 to 18, wherein each of the two first semiconductor elements is a MOSFET;
the first electrode is a drain electrode;
the second electrode is a source electrode; and
the third electrode is a gate electrode.

REFERENCE CHARACTERS

A1, B1, B2, B3, C1, C2, D1: Semiconductor device
1: First switching part
10a: Obverse face
10b: Reverse face
11: First semiconductor element
11a: First element obverse face
11b: First element reverse face
111: First electrode
112: Second electrode
113: Third electrode
12: Resin member
13: Wiring layer
14: Obverse terminal part
141: First pad part
142: Second pad part
15: Reverse terminal part
151: Pad part
161-164: Interlayer electrode
2: Second switching part
20a: Obverse face
20b: Reverse face
21: Second semiconductor element
21a: Second element obverse face
21b: Second element reverse face
211: Fourth electrode
212: Fifth electrode
213: Sixth electrode
22: Resin member
23: Wiring layer
24: Obverse terminal part
241: First pad part
242: Second pad part
25: Reverse terminal part
251: Pad part
261-264: Interlayer electrode
30: Insulating substrate
30a: Obverse face
30b: Reverse face
311: Power wiring part
321: Signal wiring part
311a: Pad part
311b: Pad part
311c: Extending part
312: Power wiring part
312a: Pad part
312a: Pad part
312b: Pad part
312c: Protruding part
312s: slit
313: Power wiring part
313a: Pad part
313b: Pad part
313c: Protruding part
321A, 321B: Signal wiring part
322A, 322B: Signal wiring part
323: Signal wiring part
324: Signal wiring part
329: Signal wiring part
33A, 33B: Conductive substate
34A, 34B: Insulating layer
41, 42, 43: Power terminal
44A, 44B, 45A, 45B, 46, 47, 48: Signal terminal
441, 451, 471: Holder
442, 452, 472: Metal pin
49: Insulating member
51A, 51B: Connection member
52A, 52B: Connection member
531A, 531B: Connection member
532A, 532B: Connection member
541A, 541B: Connection member
542A, 542B: Connection member
55: Connection member
55: Connection member
57A, 57B: Connection member
571A, 571B: Band-shaped part
572A, 572B: Linking part
60: Heat dissipation plate
61: Case
62: Frame part
63: Top plate
641-644: Terminal pedestal
65: Resin member
7: Sealing member
71: Resin obverse face
72: Resin reverse face
73, 74: Resin side face
91: Thermistor

1. A semiconductor device comprising:
two first semiconductor elements each having a first electrode, a second electrode, and a third electrode, with a switching operation being controlled depending on a first driving signal inputted to the third electrode;
a first conductor electrically connecting the second electrodes of the two first semiconductor elements;
a second conductor electrically connecting the second electrodes of the two first semiconductor elements; and
a first power terminal electrically connected to the first conductor and electrically conducting to the second electrodes of the two first semiconductor elements;
wherein the two first semiconductor elements are connected in parallel with each other,
a first conduction path and a second conduction path are provided by the first conductor and the second conductor, respectively, between the second electrodes of the two first semiconductor elements,
the first conduction path and the second conduction path are at least partially in parallel, and
a combined inductance of the first conduction path and the second conduction path is smaller than an inductance of the first conduction path.

2. The semiconductor device according to claim 1, wherein an inductance of the second conduction path is smaller than the inductance of the first conduction path.

3. The semiconductor device according to claim 1, wherein a length of the second conduction path is shorter than a length of the first conduction path

4. The semiconductor device according to claim 1 further comprising:
a first wiring part and a second wiring part spaced apart from each other; and
a first connection member electrically connected to the second electrodes of the two first semiconductor elements,
wherein the first wiring part is electrically connected to the first electrodes of the two first semiconductor elements,
the second wiring part is joined by the first connection member, thereby electrically connected to the second electrodes of the two first semiconductor elements via the first connection member, and
the first conductor includes a part of the first connection member and a part of the second wiring part.

5. The semiconductor device according to claim 4, wherein each of the two first semiconductor elements has a first element obverse face and a first element reverse face spaced apart from each other in a thickness direction of the first semiconductor elements, and
in each of the two first semiconductor elements, the first electrode is disposed on the first element reverse face, and the second electrode and the third electrode are disposed on the first element obverse face.

6. The semiconductor device according to claim 5, wherein each of the two first semiconductor elements is mounted on the first wiring part with the first element reverse face facing the first wiring part.

7. The semiconductor device according to claim 6, wherein the second conductor includes a second connection member, and
the second connection member is joined to the second electrodes of the two first semiconductor elements.

8. The semiconductor device according to claim 7, wherein the second connection member is a bonding wire.

9. The semiconductor device according to claim 6, wherein the first connection member includes two band-shaped parts spaced apart from each other, and a linking part connected to and disposed between the two band-shaped parts,
one of the two band-shaped parts is joined to the second electrode of one of the two first semiconductor elements and to the second wiring part,
the other of the two band-shaped parts is joined to the second electrode of the other of the two first semiconductor elements and to the second wiring part,
the first conductor includes the two band-shaped parts and a portion of the second wiring part interposed between joints of the two band-shaped parts, and
the second conductor includes the linking part and portions of the two band-shaped parts, each of which extends from a joint of the second electrode to the linking part.

10. The semiconductor device according to claim 9, wherein the linking part is connected to portions of the two band-shaped parts, which overlap with the two first semiconductor elements as viewed in the thickness direction.

11. The semiconductor device according to claim 6 further comprising:
a resin member overlapping with at least a part of each of the two first semiconductor elements;
a wiring layer disposed above the first element obverse faces of the two first semiconductor elements and covered by the resin member; and
a terminal part exposed from the resin member and joined by the first connection member,
wherein the terminal part is electrically connected to the second electrodes of the two first semiconductor elements, and
the wiring layer is electrically connected to the second electrodes of the two first semiconductor elements and overlaps with the second electrodes of the two first semiconductor elements as viewed in the thickness direction.

12. The semiconductor device according to claim 11, wherein the terminal part includes two pad parts spaced apart from each other and joined by the first connection member,
one of the two pad parts overlaps with the second electrodes of one of the two first semiconductor elements as viewed in the thickness direction, and
the other of the two pad parts overlaps with the second electrodes of the other of the two first semiconductor elements as viewed in the thickness direction.

13. The semiconductor device according to claim 6 further comprising:
two second semiconductor elements each having a fourth electrode, a fifth electrode, and a sixth electrode, with a switching operation being controlled depending on a second driving signal inputted to the sixth electrode;
a third conductor electrically connecting the fifth electrodes of the two second semiconductor elements;
a fourth conductor electrically connecting the fifth electrodes of the two second semiconductor elements; and
a second power terminal electrically connected to the third conductor and the fifth electrodes of the two second semiconductor elements,
wherein the two second semiconductor elements are connected in parallel with each other,
a third conduction path and a fourth conduction path are provided between the fifth electrodes of the two second semiconductor elements and extend through the third conductor and the fourth conductor, respectively,
the third conduction path and the fourth conduction path are at least partially in parallel, and
a combined inductance of the third conduction path and the fourth conduction path is smaller than an inductance of the third conduction path.

14. The semiconductor device according to claim 13, wherein an inductance of the fourth conduction path is smaller than the inductance of the third conduction path.

15. The semiconductor device according to claim 13, wherein a length of the fourth conduction path is shorter than a length of the third conduction path.

16. The semiconductor device according to claim 13 further comprising:
a third wiring part spaced apart from the first wiring part and the second wiring part; and
a third connection member electrically connected to the fifth electrodes of the two second semiconductor elements,
wherein the second wiring part is electrically connected to the fourth electrodes of the two second semiconductor elements,
the third wiring part is joined by the third connection member, thereby electrically conducting to the fifth electrodes of the two second semiconductor elements via the third connection member, and
the third conductor includes a part of the third connection member and a part of the third wiring part.

17. The semiconductor device according to claim 16 further comprising a third power terminal connected to the first wiring part,
wherein the second power terminal and the third power terminal are input terminals for a direct voltage,
the direct voltage is converted into an alternating voltage by switching operations of the two first semiconductor elements and the two second semiconductor elements, and
the first power terminal is an output terminal for the alternating voltage.

18. The semiconductor device according to claim 13, wherein each of the two second semiconductor elements is a MOSFET,
the fourth electrode is a drain electrode,
the fifth electrode is a source electrode, and
the sixth electrode is a gate electrode.

19. The semiconductor device according to claim 1, wherein each of the two first semiconductor elements is a MOSFET,
the first electrode is a drain electrode,
the second electrode is a source electrode, and
the third electrode is a gate electrode.
